(19) United States
(12) Patent Application Publication
(10) Pub. No.: US 2025/0164975 A1
(43) Pub. Date: May 22, 2025

(54) INFORMATION PROCESSING METHOD, RECORDING MEDIUM, AND INFORMATION PROCESSING APPARATUS

(71) Applicant: Tokyo Electron Limited, Tokyo (JP)

(72) Inventors: Masaki KITSUNEZUKA, Sapporo City (JP); Keiichi TAKAHASHI, Miyagi (JP)

(73) Assignee: Tokyo Electron Limited, Tokyo (JP)

(21) Appl. No.: 19/034,684

(22) Filed: Jan. 23, 2025

Related U.S. Application Data
(63) Continuation of application No. PCT/JP2023/026620, filed on Jul. 20, 2023.

(30) Foreign Application Priority Data
Jul. 25, 2022 (JP) 2022-118046
Jul. 25, 2022 (JP) 2022-118047

(51) Int. Cl. G05B 19/418

(52) U.S. Cl. CPC G05B 19/4184; G05B 2219/45031

(57) ABSTRACT

An information processing method includes, by an information processing apparatus: acquiring monitoring data which includes a plurality of items related to a state of each process performed by a target apparatus; generating a dimensional compression model for compressing the number of dimensions of the monitoring data; inputting the monitoring data into the dimensional compression model to convert the monitoring data into a low-dimensional representation; and outputting the monitoring data converted into the low-dimensional representation. In addition, the monitoring data may include a plurality of items classified into a plurality of categories, and the information processing apparatus may generate the dimensional compression model for each category, and may input the monitoring data into a dimensional compression model corresponding to each category to convert the monitoring data into a low-dimensional representation for each category.

### CROSS-REFERENCE TO RELATED APPLICATIONS

This application is a bypass continuation application of international application No. PCT/JP2023/026620 having an international filing date of Jul. 20, 2023 and designating the United States, the international application being based upon and claiming the benefit of priority from Japanese Patent Applications No. 2022-118046 and No. 2022-118047, filed on Jul. 25, 2022, the entire contents of each are incorporated herein by reference.

### TECHNICAL FIELD

The present disclosure relates to an information processing method, a recording medium, and an information processing apparatus.

### BACKGROUND

Ivan Tan, Russell Dover, Madhukar Reddy, “Enabling Machine Learning for Increased Tool Matching and Greater Process Control”, AEC/APC Symposium Asia 2021 introduces that signals obtained from a sensor in a chamber are analyzed using principal component analysis or the like in a semiconductor manufacturing process.

### SUMMARY

The information processing method according to one embodiment includes, by an information processing apparatus: acquiring monitoring data which includes a plurality of items related to a state of each process performed by a target apparatus; generating a dimensional compression model in which the number of dimensions of the monitoring data is compressed; inputting the monitoring data into the dimensional compression model to convert the monitoring data into a low-dimensional representation; and outputting the monitoring data converted into the low-dimensional representation.

### BRIEF DESCRIPTION OF DRAWINGS

FIG. 1 is a schematic diagram for explaining an example of an information processing system according to a first embodiment.

FIG. 2 is a block diagram illustrating an example of a configuration of an information processing apparatus according to the first embodiment.

FIG. 3 is a schematic diagram for explaining an example of a configuration of monitoring data stored in a monitoring data storage.

FIG. 4 is a flowchart illustrating an example of a procedure of a visualization process for each category performed by the information processing apparatus according to the first embodiment.

FIG. 5 is a schematic diagram illustrating an example of visualization for each category.

FIG. 6 is a flowchart illustrating an example of a procedure of a visualization process of variations in a fleet unit and a chamber unit, which is performed by the information processing apparatus according to the first embodiment.

FIG. 7 is a schematic diagram illustrating an example of visualization of variations in a fleet unit and a chamber unit.

FIG. 8 is a schematic diagram illustrating an example of visualization of variations in a fleet unit and a chamber unit.

FIG. 9 is a schematic diagram illustrating an example of visualization of variations in a fleet unit and a chamber unit based on principal component analysis.

FIG. 10 is a schematic diagram illustrating an example of visualization of variations in a fleet unit and a chamber unit based on principal component analysis.

FIG. 11 is a schematic diagram illustrating an example of a configuration of label information.

FIG. 12 is a flowchart illustrating an example of a procedure of a visualization process based on the label information, which is performed by the information processing apparatus according to the first embodiment.

FIG. 13 is a schematic diagram illustrating an example of the visualization process based on the label information.

FIG. 14 is a flowchart illustrating an example of a procedure of a visualization process using scale conversion based on the label information, which is performed by the information processing apparatus according to the first embodiment.

FIG. 15 is a schematic diagram illustrating an example of the visualization process using scale conversion based on the label information.

FIG. 16 is a flowchart illustrating an example of a procedure of a visualization process using an autoencoder, which is performed by the information processing apparatus according to the first embodiment.

FIG. 17 is a schematic diagram illustrating an example of the visualization process using the autoencoder.

FIG. 18 is a flowchart illustrating a procedure of a chamber verification process performed by the information processing system according to the present embodiment.

FIG. 19 is a schematic diagram for explaining an example of data collection plan information.

FIG. 20 is a schematic diagram for explaining an example of the data collection plan information.

FIG. 21 is a schematic diagram illustrating an example of sensor ranking.

FIG. 22 is a flowchart for explaining an outline of an analysis process performed by an information processing apparatus according to a second embodiment.

FIG. 23 is a flowchart illustrating a procedure of a temporal change monitoring process performed by the information processing apparatus according to the second embodiment.

FIG. 24 is a schematic diagram for explaining the temporal change monitoring process.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### <System Configuration>

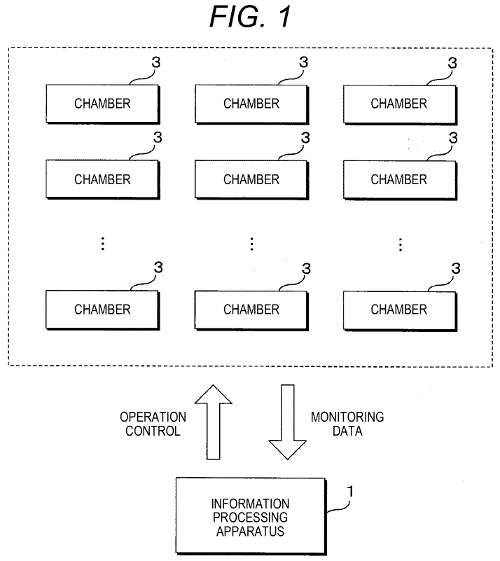

FIG. 1 is a schematic diagram for explaining an example of an information processing system according to a first embodiment. The information processing system according to the present embodiment includes an information processing apparatus 1 and a plurality of chambers (target apparatuses) 3. The chamber 3 is an apparatus for manufacturing a semiconductor, and is an apparatus for performing a process such as chemical vapor deposition (CVD), sputtering, or etching. The information processing system according to the present embodiment is a system having a configuration in which, for example, a plurality of chambers 3 are installed in a semiconductor manufacturing factory, and the information processing apparatus 1 controls operations of these plurality of chambers 3. In the present embodiment, one information processing apparatus 1 controls the plurality of chambers 3. However, the present disclosure is not limited thereto, and a plurality of information processing apparatuses 1 may control the plurality of chambers 3.

Each chamber 3 performs various processes on a wafer to be transferred under the control of the information processing apparatus 1, thereby manufacturing a semiconductor. A plurality of sensors, such as temperature sensors and pressure sensors, are installed in each chamber 3, and various types of information, which are detected by the sensors when various types of processes are performed on the wafer, are output to the information processing apparatus 1 as monitoring data related to these types of processes.

The information processing apparatus 1 controls the operation of one or more chambers 3 in accordance with, for example, settings (recipes) related to semiconductor processes input in advance by a user such as a worker performing a work of manufacturing a semiconductor or an administrator of the system. The information processing apparatus 1 performs various types of processes on one or more wafers by the operation of the chamber 3, thereby manufacturing a semiconductor. The information processing apparatus 1 receives monitoring data, which includes various types of information collected by a sensor or the like from the chamber 3 in accordance with the operation of the chamber 3, and records and accumulates the received monitoring data in a database. Further, the information processing apparatus 1 according to the present embodiment performs various types of an arithmetic process on the monitoring data recorded in the database, and displays arithmetic results in the form of visualization on a graph or the like. Thus, the user can be expected to analyze individual differences, causes of malfunctions, or the like related to the plurality of chambers 3 based on the visualized monitoring data.

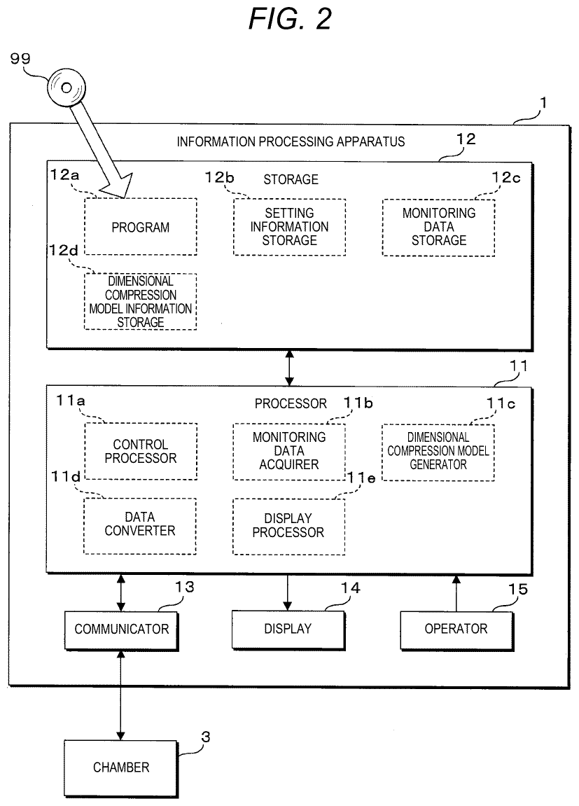

FIG. 2 is a block diagram illustrating an example of a configuration of the information processing apparatus 1 according to the first embodiment. The information processing apparatus 1 according to the present embodiment includes a processor 11, a storage 12, a communicator (transceiver) 13, a display 14, an operator 15, and the like. In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and performs a program 12a stored in the storage 12, thereby performing various processes such as a process of controlling the operation of the chamber 3 and a process of collecting the monitoring data related to the chamber 3.

The storage 12 is configured by using, for example, a large-capacity storage apparatus such as a hard disk. The storage 12 stores various types of programs to be executed by the processor 11 and various types of data necessary for the process of the processor 11. In the present embodiment, the storage 12 stores the program 12a to be executed by the processor 11. Further, the storage 12 includes a setting information storage 12b that stores various types of setting information related to the process performed by the chamber 3, a monitoring data storage 12c that stores the monitoring data acquired from the chamber 3, and a dimensional compression model information storage 12d that stores information related to a dimensional compression model for performing a dimensional compression process on the monitoring data.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage 12. However, for example, the program 12a may be written into the storage 12 during a manufacturing stage of the information processing apparatus 1. For example, as the program 12a, the information processing apparatus 1 may acquire those which are distributed by a remote server device or the like through communication. For example, the program 12a may be written into the storage 12 of the information processing apparatus 1 after a writing apparatus reads data recorded in the recording medium 99. The program 12a may be provided in the form of distribution through a network, or may be provided in the form recorded in the recording medium 99.

The setting information storage 12b of the storage 12 stores various types of setting information related to the process performed in the chamber 3. The setting information includes information which may be referred to as a recipe of a semiconductor process, and may include, for example, settings such as a pressure and a flow rate of a gas in an etching process, a voltage and a frequency of a discharge, and a temperature of the wafer. Further, the recipe includes, for example, information such as a performance time of the semiconductor process and settings for each step of the semiconductor process. The information processing apparatus 1 receives an input of the setting information by the user through the operator 15, and stores the received setting information in the setting information storage 12b.

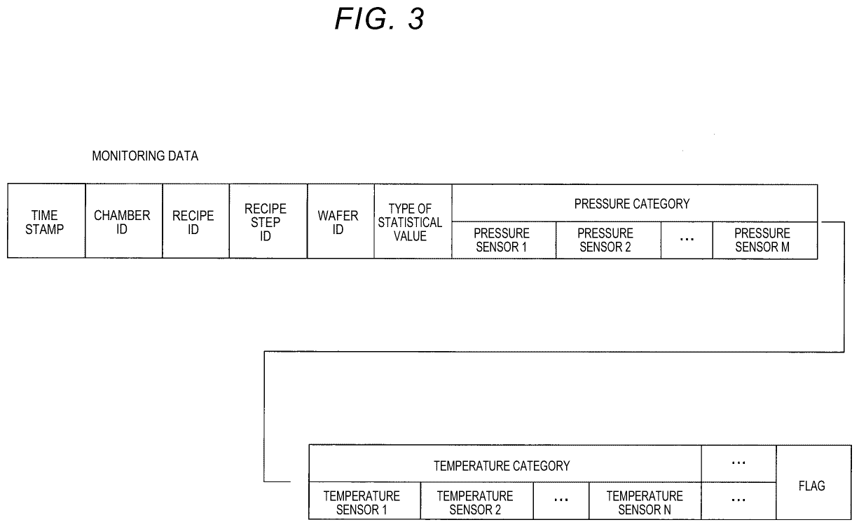

The monitoring data storage 12c is a database that records and accumulates monitoring data acquired by the information processing apparatus 1 from the plurality of chambers 3. FIG. 3 is a schematic diagram for explaining an example of a configuration of the monitoring data stored in the monitoring data storage 12c. The illustrated monitoring data is data that stores information detected by a plurality of sensors installed in the chamber 3 in association with information such as “time stamp”, “chamber ID”, “recipe ID”, “recipe step ID”, “wafer ID”, “type of statistical values”, and “flags”, for example. The information detected by the plurality of sensors is classified and stored for each sensor category, and in the present example, the information is classified into categories such as “pressure category” and “temperature category”.

The chamber 3 according to the present embodiment is installed with, for example, M pressure sensors and N temperature sensors. The M pressure sensors are disposed at appropriate locations in the chamber 3, and detect pressures at each location in the chamber 3. The illustrated monitoring data represents detection values of the first pressure sensor as “pressure sensor 1”, detection values of the second pressure sensor as “pressure sensor 2”, . . . , and detection values of the M-th pressure sensor as “pressure sensor M”. Similarly, the N temperature sensors are disposed at appropriate locations in the chamber 3, and detect the temperature at each location in the chamber 3. The illustrated monitoring data represents detection values of the first temperature sensor as “temperature sensor 1”, detection values of the second temperature sensor as “temperature sensor 2”, . . . , and detection values of the N-th temperature sensor as “temperature sensor N”. The chamber 3 may be installed with sensors of various categories other than the pressure sensor and the temperature sensor, and the monitoring data may include detection values of more categories of sensors. The monitoring data may include, for example, information of a category such as flow rate, pressure, temperature, or plasma emission spectroscopy of a gas related to the semiconductor processing process, and may include, for example, information of a category such as maintenance information of the chamber 3 or part wear rate, or may include information of various categories other than these.

The “time stamp” of the monitoring data is information such as the date and time when the wafer process of the chamber 3 is started, the date and time when the detection values of each sensor in the chamber 3 are acquired, the date and time when the chamber 3 generates the monitoring data, the date and time when the chamber 3 transmits the monitoring data to the information processing apparatus 1, or the date and time when the information processing apparatus 1 acquires the monitoring data. The “chamber ID” is identification information uniquely assigned to each chamber 3, and may be predetermined by a user such as a designer or an administrator of the information processing system according to the present embodiment, for example.

The recipe ID is identification information uniquely assigned to the setting information of the process to be performed in the chamber 3, is configured by letters, numbers, or a combination thereof, and may be predetermined by a user such as an administrator of the information processing system or a worker performing a semiconductor manufacturing work, for example. The recipe includes setting information about one or more processes to be performed on the wafer. In the present embodiment, each process in which the setting information is included in the recipe is referred to as a recipe step. The “recipe step ID” of the monitoring data is identification information assigned to one or more steps included in the recipe designated by the above-described “recipe ID”.

The wafer ID is identification information uniquely assigned to the wafer processed in each chamber 3, is configured by letters, numbers, or a combination thereof, and may be designated for each wafer by a user such as an administrator of the information processing system according to the present embodiment or an administrator of manufacturing of a semiconductor, for example.

Each sensor in the chamber 3 performs detection a plurality of times while the process of one recipe step is performed, and in the present embodiment, a value of each sensor stored in the monitoring data is an average value, a minimum value, or a maximum value of the detection results of a plurality of times. “Type of statistical values” is information representing whether the value of each sensor stored as the monitoring data is one of a plurality of types of the statistical values such as the average value, the minimum value, or the maximum value. In the information processing system according to the present embodiment, the chamber 3 samples and acquires output values from each sensor at predetermined sampling periods, and stores the output values in a storage or the like of the chamber 3. The chamber 3 calculates statistical values by performing arithmetic on the stored time series output values of each sensor using a statistical method designated in advance by the user for each recipe step set in advance, for example. The chamber 3 transmits the calculated statistical values to the information processing apparatus 1, and the information processing apparatus 1 receives the statistical values and stores the statistical values as the monitoring data in the monitoring data storage 12c. The chamber 3 may transmit the time series output values of each sensor to the information processing apparatus 1, and the information processing apparatus 1 may calculate statistical values based on the time series output values and store the statistical values as the monitoring data in the monitoring data storage 12c. Further, the information processing apparatus 1 may store the output values of the time series of each sensor as the monitoring data, instead of storing the statistical values as the monitoring data in the monitoring data storage 12c, and calculate the statistical values as necessary.

The “flag” is a result of the process of the wafer, and is information representing whether a label of, for example, a non-defective product or a defective product is assigned. In the present embodiment, the “flag” is information used when performing, for example, an analysis process of the monitoring data. Therefore, the “flag” does not need to be included in the monitoring data acquired from the chamber 3, and for example, may be information to be added by the information processing apparatus 1 as necessary, or for example, may be information to be added by a user such as an analyst analyzing the monitoring data upon analysis.

Each chamber 3 repeats detection of pressure, temperature, and the like by the plurality of installed sensors at an appropriate cycle such as once every 100 milliseconds or once every second, for example, when the process is performed on the wafer. Each chamber 3 acquires detection values of the sensor in this cycle, calculates statistical values of a plurality of detection values each time the process of one recipe step is completed, generates the illustrated monitoring data, and transmits the illustrated monitoring data to the information processing apparatus 1. The information processing apparatus 1 receives the monitoring data from the plurality of chambers 3, and stores the received monitoring data in the monitoring data storage 12c. In this case, the monitoring data storage 12c stores monitoring data corresponding to the number of recipe steps of the process performed on one wafer.

However, the information processing apparatus 1 may store the detection values themselves of each sensor, instead of storing the plurality of detection values of the each sensor as statistical values. In this case, the monitoring data storage 12c stores monitoring data corresponding to the number of times that the detection of the sensor is performed on one wafer. When the detection cycles of the plurality of sensors provided in the chamber 3 are different from each other, for example, the monitoring data may be created in alignment with the sensor having the shortest cycle. Further, for example, the information processing apparatus 1 may acquire detection values detected by each sensor as representative values at predetermined timings of the process of the wafer, for example, 10 seconds after the start of the process, and may store the monitoring data including the representative values. Further, when the information processing apparatus 1 stores the statistical values, not all the sections in one recipe step may be targets of the statistical value calculation, but for example, only the predetermined sections excluding the first and last sections of the recipe step may be targets of the statistical value calculation.

The dimensional compression model information storage 12d of the storage 12 stores information related to the dimensional compression model generated by the information processing apparatus 1 based on the monitoring data stored in the monitoring data storage 12c. The information related to the dimensional compression model may include, for example, configuration information representing that the dimensional compression model has any configuration, and information such as parameter values inside the dimensional compression model. The information processing apparatus 1 of the present embodiment can perform dimensional compression of the monitoring data by using the dimensional compression model stored in the dimensional compression model information storage 12d, thereby graphically displaying the monitoring data having a large number of values (that is, multi-dimensions) in two dimensions, three dimensions, or the like.

The communicator 13 of the information processing apparatus 1 is connected to the plurality of chambers 3 through a cable such as a communication line or a signal line, and transmits and receives data to and from the chamber 3 through the cable. The communicator 13 may communicate with the chamber 3 through wireless communication. In the present embodiment, the communicator 13 transmits control data supplied from the processor 11 to the chamber 3. Further, the communicator 13 receives the monitoring data transmitted from the chamber 3, and supplies the received monitoring data to the processor 11.

The display 14 is configured by using a liquid crystal display or the like, and displays various images, characters, and the like based on the process of the processor 11. The display 14 displays, for example, various types of information related to an operation state of the chamber 3, and displays a warning message or the like when an abnormality is detected in the operation state of the chamber 3. Further, in the present embodiment, the display 14 displays a screen for analyzing individual differences, malfunctions, or the like of the chamber 3, based on the monitoring data acquired from the plurality of chambers 3.

The operator 15 receives a user operation and notifies the processor 11 of the received operation. For example, the operator 15 receives the user operation by an input device such as a mechanical button or a touch panel provided on a surface of the display 14. For example, the operator 15 may be an input device such as a mouse and a keyboard, and these input devices may be configured to be detachable from the information processing apparatus 1.

The storage 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display 14, the operator 15, and the like, for example.

Further, in the information processing apparatus 1 according to the present embodiment, the processor 11 reads and performs the program 12a stored in the storage 12, thereby implementing a control processor 11a, a monitoring data acquirer 11b, a dimensional compression model generator 11c, a data converter 11d, a display processor 11e, and the like as software-like functional units in the processor 11.

The control processor 11a performs a process of controlling the operations of the plurality of chambers 3 based on the setting information stored in the setting information storage 12b. For example, when the etching process is performed on the wafer in the chamber 3, the control processor 11a acquires information such as the pressure and the flow rate set in the setting information, the voltage and the frequency of the discharge, and the temperature of the wafer. The control processor 11a can cause the chamber 3 to perform the etching process under the set conditions by transmitting the acquired setting information to each chamber 3.

An apparatus, which serves as a monitoring target of the information processing apparatus 1 according to the present embodiment, is not limited to the chamber 3, and may be various substrate processing apparatuses, and may be hardware units such as a high frequency unit or a gas supply unit constituting the apparatuses. Further, the process performed by the substrate processing apparatuses is not limited to the etching process, and may be various processes such as a substrate (wafer) processing process, a substrate pre-post process, a substrate transfer process, a wafer-less dry cleaning process, a plasma health check process, or a sensor automatic check process, for example. The information processing apparatus 1 controls an operation of the substrate processing apparatus, and stores and accumulates monitoring data obtained from the substrate processing apparatus.

The monitoring data acquirer 11b acquires the monitoring data from the chamber 3 in which the process is performed on the wafer, and performs a process of storing the acquired monitoring data in the monitoring data storage 12c. For example, when the process is performed on the wafer, the chamber 3 repeatedly detects pressures, temperatures, and the like by the plurality of installed sensors at predetermined cycles, and collectively transmits detection values of the plurality of sensors to the information processing apparatus 1 as the monitoring data. The monitoring data acquirer 11b acquires the monitoring data by receiving the monitoring data periodically transmitted by the plurality of chambers 3 in accordance with the performance of the process by the communicator 13, and stores the acquired monitoring data in the monitoring data storage 12c. In this case, the monitoring data acquirer 11b may perform, for example, a process of adding a time stamp to the monitoring data acquired from the chamber 3, or an arithmetic process of detection values of the sensors included in the monitoring data, as necessary. For example, the statistical values of the detection values of the sensor are stored as the monitoring data. However, when the chamber 3 transmits the detection values of the sensors without performing the calculation of the statistical values, the monitoring data acquirer 11b may perform the calculation of the statistical values. In this case, for example, the monitoring data acquirer 11b extracts monitoring data, which has a common chamber ID, recipe ID, recipe step ID, and wafer ID, from a plurality of time series data periodically received from the chamber 3. The monitoring data acquirer 11b calculates statistical values, such as the average value of the detection values of each sensor, for a plurality of extracted time series data. The monitoring data acquirer 11b can generate one set of monitoring data that includes the calculated statistical values and the like for each recipe step performed in the chamber 3, and can store the generated data in the monitoring data storage 12c. Further, when a plurality of types of statistical values can be stored for one recipe step, a set of monitoring data having the number of types of statistical values per one recipe step may be stored in the monitoring data storage 12c.

The dimensional compression model generator 11c uses the plurality of monitoring data stored in the monitoring data storage 12c to perform a process of generating a dimensional compression model for dimensionally compressing the monitoring data. In the present embodiment, the dimensional compression model generator 11c treats the monitoring data in a wafer unit, and generates the dimensional compression model for dimensionally compressing the monitoring data in order to visualize differences in process performed on each wafer. In the present embodiment, the dimensional compression model generator 11c generates the dimensional compression model by a method of machine learning based on so-called unsupervised learning using principal component analysis (PCA), but the present disclosure is not limited thereto. The dimensional compression model generator 11c may generate the dimensional compression model, for example, by a method such as independent component analysis (ICA), factor analysis, t-distributed stochastic neighbor embedding (t-SNE), hierarchical clustering, or latent semantic analysis (LSA). Since the generation of the dimensional compression model by these methods is an existing technique, a detailed description thereof will be omitted. The dimensional compression model generator 11c stores the generated information related to the dimensional compression model in the dimensional compression model information storage 12d.

The data converter 11d uses the dimensional compression model stored in the dimensional compression model information storage 12d to perform a process of converting the monitoring data stored in the monitoring data storage 12c into display data in which dimensions are compressed. The data converter 11d inputs each monitoring data of other dimensions stored in the monitoring data storage 12c into the dimensional compression model, and converts the monitoring data into display data by acquiring monitoring data with a reduced number of dimensions such as two dimensions or three dimensions output by the dimensional compression model.

The display processor 11e performs a process of visualizing the display data converted by the data converter 11d, that is, the monitoring data reduced in dimensions such as two dimensions or three dimensions, and displaying the display data, that is, the monitoring data on the display 14. In the present embodiment, the display processor 11e creates a graph such as a histogram, a box and whisker plot, a violin chart, a swarm plot, a scattering diagram, a density contour diagram, or a heat map based on the two-dimensional display data, and displays the created graph on the display 14.

### <Display Process of Monitoring Data>

The information processing apparatus 1 performs the process of visualizing the monitoring data stored in the monitoring data storage 12c and displaying the monitoring data on the display 14. In the present embodiment, the information processing apparatus 1 visualizes the monitoring data in a wafer unit. The information processing apparatus 1 according to the present embodiment displays the monitoring data by using, for example, at least one of the following methods (1) to (5).
(1) Visualization Process for Each Category
(2) Visualization Process of Variations in Fleet Unit and Chamber Unit
(3) Visualization Process Based on Label Information
(4) Visualization Process Using Scale Conversion Based on Label Information
(5) Visualization Process Using Autoencoder

### (1) Visualization Process for Each Category

In the information processing system according to the present embodiment, the information included in the monitoring data (for example, detection values of the sensor) is classified into a plurality of categories. In the example of the monitoring data illustrated in FIG. 3, the information is classified into a plurality of categories such as a pressure category and a temperature category. The information processing apparatus 1 according to the present embodiment generates a dimensional compression model for each category in a wafer unit of the monitoring data, performs dimensional compression of the monitoring data for each category using the generated dimensional compression model, and performs visualization of the monitoring data in a wafer unit for each category.

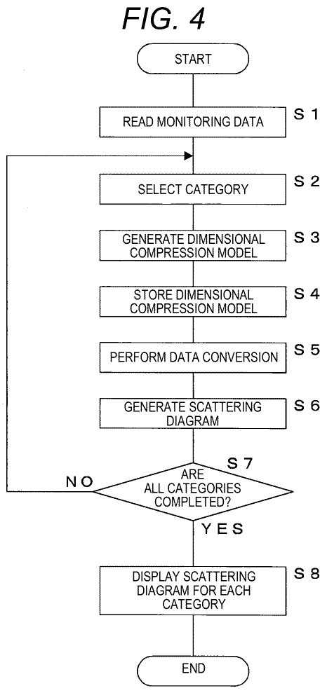

FIG. 4 is a flowchart illustrating an example of a procedure of a visualization process for each category performed by the information processing apparatus 1 according to the first embodiment. The monitoring data acquirer 11b of the processor 11 of the information processing apparatus 1 according to the present embodiment reads the plurality of monitoring data stored in the monitoring data storage 12c of the storage 12 (step S1). In this case, the monitoring data acquirer 11b may receive conditions, such as periods of monitoring data serving as a visualization target, from the user, and in this case, the monitoring data acquirer 11b extracts monitoring data such as the received periods as conditions.

The dimensional compression model generator 11c of the processor 11 selects one category to be processed from among the plurality of categories included in the monitoring data (step S2). The dimensional compression model generator 11c generates a dimensional compression model for compressing the number of dimensions of the selected category of the monitoring data read in step S1, for example, by a method of principal component analysis using the information of the selected category as a target (step S3). The dimensional compression model generator 11c stores the information related to the dimensional compression model generated in step S3 in the dimensional compression model information storage 12d of the storage 12 (step S4).

For example, in the monitoring data illustrated in FIG. 3, the pressure category includes information of detection values of M sensors, and the temperature category includes information of detection values of N sensors. For example, when the recipe step performs a P-step process on one wafer and stores Q-type values, which serve as statistical values, as monitoring data, the monitoring data about the pressure category is (M×P×Q)-dimensional data. The dimensional compression model generator 11c generates a dimensional compression model for compressing the (M×P×Q)-dimensional data into two-dimensional data. Similarly, in FIG. 3, the monitoring data for the temperature category is (N×P×Q)-dimensional data, and the dimensional compression model generator 11c generates a dimensional compression model for compressing the (N×Px Q)-dimensional data into two-dimensional data.

For example, when M detection values, P-step recipe steps, and Q-types of statistical values exist, the monitoring data may be (M×P×Q) dimensions as described above. However, all the information about the M detection values, the P-step recipe steps, and the Q-type statistical values may not necessarily be the targets of the dimensional compression. For example, the user may select any M′ detection values from the M detection values, select a recipe step of a P′ step among the P steps, and select any Q′-type statistical value from among the Q types. The information processing apparatus 1 may generate (M′×P′×Q′)-dimensional monitoring data using the selected combination, and may generate a dimensional compression model for dimensionally compressing the generated monitoring data.

Next, the data converter 11d of the processor 11 inputs the monitoring data read in step S1 into the dimensional compression model generated in step S3, and converts the three-dimensional or more monitoring data into display data that is two-dimensionally compressed by acquiring data that is output by the dimensional compression model (step S5). The data converter 11d generates a scattering diagram in which the display data is visualized based on the display data obtained in step S5 (step S6). In the flowchart, visualization is performed by displaying a scattering diagram as an example. However, the present disclosure is not limited thereto, and various graphs other than the scattering diagram may be displayed.

The processor 11 determines whether the process such as dimensional compression and creation of the scattering diagram for all the categories included in the monitoring data has been completed (step S7). When the process is not completed for all the categories (S7: NO), the processor 11 returns the process to step S2, selects another category, and repeats the same process. When the process has been completed for all the categories (S7: YES), the display processor 11e of the processor 11 displays the scattering diagram for each category generated in step S6 on the display 14 (step S8), and completes the process.

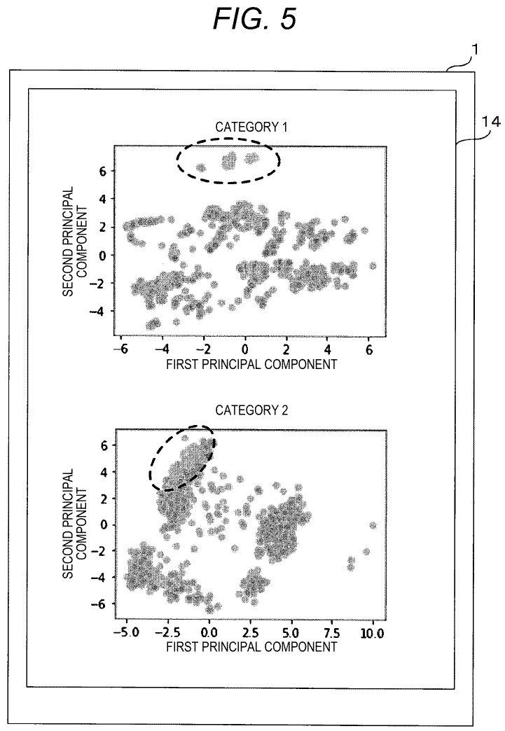

FIG. 5 is a schematic diagram illustrating an example of visualization for each category. In the illustrated example, scattering diagrams, in which three-dimensional or more monitoring data is compressed two-dimensionally, and one monitoring data is plotted as one dot on a two-dimensional plane, are displayed for each category. For example, the information processing apparatus 1 generates the scattering diagrams for two categories of Category 1 and Category 2 included in the monitoring data, and vertically displays the two scattering diagrams on the display 14. In the present embodiment, one dot displayed on the scattering diagram by the information processing apparatus 1 is a dot in which coordinates are determined based on two-dimensional information obtained by dimensionally compressing the plurality of information acquired from one wafer processed in the semiconductor manufacturing process.

A portion surrounded by a broken line ellipse in the scattering diagram of Category 1 is a collection of monitoring data about a specific chamber 3, and the monitoring data about the chamber 3 deviates from monitoring data about other chambers 3. The monitoring data of the specific chamber 3 exists in a portion surrounded by a broken-line ellipse in the scattering diagram of Category 2, and the deviation from the monitoring data of other chambers 3 is not observed in the scattering diagram of Category 2. From these results, it can be inferred that the specific chamber 3 exhibits behavior, characteristics, or the like different from those of other chambers 3 in Category 1, and that Category 1 has abnormalities, individual differences, or the like.

### (2) Visualization Process of Variations in Fleet Unit and Chamber Unit

The information processing system according to the present embodiment includes the plurality of chambers 3, and the collection of the plurality of chambers 3 may be referred to as a fleet. In the information processing system according to the present embodiment, one or more monitoring data according to the sampling period of the sensor or the like is stored and accumulated for one wafer processed in one chamber 3. The information processing apparatus 1 according to the present embodiment calculates, for each of the monitoring data, an indicator of variations in a chamber unit and an indicator of variations in a fleet unit. Based on the calculated indicators, the information processing apparatus 1 visualizes each monitoring data as two-dimensional data of the indicator of variations in a chamber unit and the indicator of variations in a fleet unit.

Each monitoring data includes statistical values of detection values of the plurality of sensors classified into the plurality of categories as described above. The range, unit, and the like of each detection value may differ from sensor to sensor. For example, the information processing apparatus 1 performs scale conversion of the statistical values of the detection values for each sensor in advance, thereby converting all the statistical values included in the monitoring data such that an average thereof becomes zero and a standard deviation becomes one. Therefore, the information processing apparatus 1 can treat each monitoring data that includes the statistical values of the detection values of the plurality of sensors classified into the plurality of categories as uniform data that includes a plurality of numerical information within a predetermined range, regardless of the category. For example, as for the statistical values of the detection value of one sensor included in the monitoring data, the information processing apparatus 1 can perform data conversion by acquiring the average value and the standard deviation of the statistical values of the detection values of the sensor included in all the monitoring data serving as a target, and dividing the average value by the standard deviation after subtracting the average value from the statistical values of the detection value of the sensor. The method of converting the data is an example and the present disclosure is not limited thereto, and the information processing apparatus 1 may perform the data conversion in any method.

The information processing apparatus 1 according to the present embodiment uses a Mahalanobis distance as an indicator of variations of the monitoring data. The Mahalanobis distance is a scalar value that represents a distance of each vector for a multi-dimensional vector group. Since the method of calculating the Mahalanobis distance is an existing technique, a detailed description thereof will be omitted. However, the Mahalanobis distance is calculated based on an average and a covariance matrix of the vector group. In addition to the Mahalanobis distance, other distance indicators such as a Euclid distance or a Chebyshev distance may be used as the indicator of variations of the monitoring data.

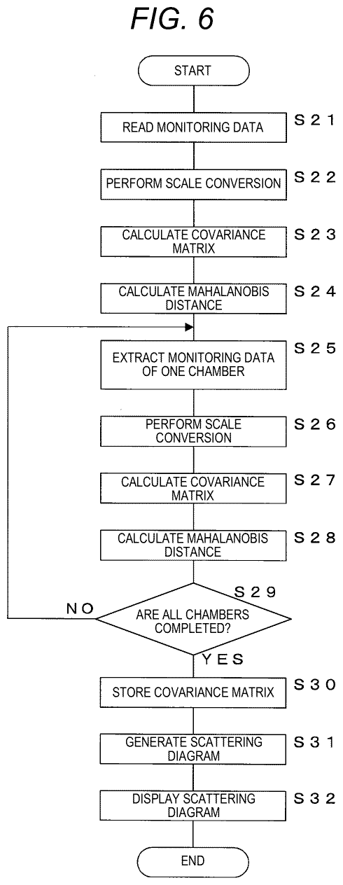

FIG. 6 is a flowchart illustrating an example of a procedure of a visualization process of variations in a fleet unit and a chamber unit, which is performed by the information processing apparatus 1 according to the first embodiment. The monitoring data acquirer 11b of the processor 11 of the information processing apparatus 1 according to the present embodiment reads the plurality of monitoring data stored in the monitoring data storage 12c of the storage 12 (step S21). The monitoring data read in step S21 is a mixture of the monitoring data related to the plurality of chambers 3.

The dimensional compression model generator 11c of the processor 11 uses all the monitoring data read in step S21 to perform scale conversion on each value (statistical value of the detection values of the sensor) included in each monitoring data (step S22). The dimensional compression model generator 11c calculates a covariance matrix for all the multi-dimensional monitoring data scale-converted in step S22 (step S23). The dimensional compression model generator 11c uses the covariance matrix calculated in step S23 to calculate the Mahalanobis distance of each monitoring data about all the monitoring data groups (step S24). The Mahalanobis distance calculated in step S24 serves as an indicator of variations of each monitoring data in a fleet unit.

Next, the dimensional compression model generator 11c extracts monitoring data about one chamber 3 from the monitoring data read in step S21 (step S25). The dimensional compression model generator 11c uses the monitoring data about one chamber 3 extracted in step S25 to perform scale conversion on each value (detection value of the sensor) included in each monitoring data (step S26). The dimensional compression model generator 11c calculates a covariance matrix for the monitoring data scale-converted in step S26 (step S27). The dimensional compression model generator 11c uses the covariance matrix calculated in step S27 to calculate a Mahalanobis distance of each monitoring data about the monitoring data group (step S28). The Mahalanobis distance calculated in step S28 serves as an indicator of variations of each monitoring data in a chamber unit.

The dimensional compression model generator 11c determines whether the calculation process of the Mahalanobis distance for all the chambers 3 has been completed in a chamber unit (step S29). When the process is not completed for all the chambers 3 (S29: NO), the dimensional compression model generator 11c returns the process to step S25, extracts monitoring data about other chambers 3, and repeats the same process. When the process has been completed for all the chambers 3 (S29: YES), the dimensional compression model generator 11c stores the covariance matrix related to all the monitoring data calculated in step S23 and the covariance matrix for each chamber 3 calculated in step S27 in the dimensional compression model information storage 12d of the storage 12 as information related to the dimensional compression model (step S30).

Through the processes in steps S21 to S30 described above, the Mahalanobis distance in a fleet unit and the Mahalanobis distance in a chamber unit are calculated for each monitoring data. For example, the display processor 11e of the processor 11 generates a scattering diagram in which each monitoring data is plotted by representing a horizontal axis as a Mahalanobis distance in a fleet unit and a vertical axis as a Mahalanobis distance in a chamber unit (step S31). The display processor 11e displays the scattering diagram generated in step S31 on the display 14 (step S32), and completes the process.

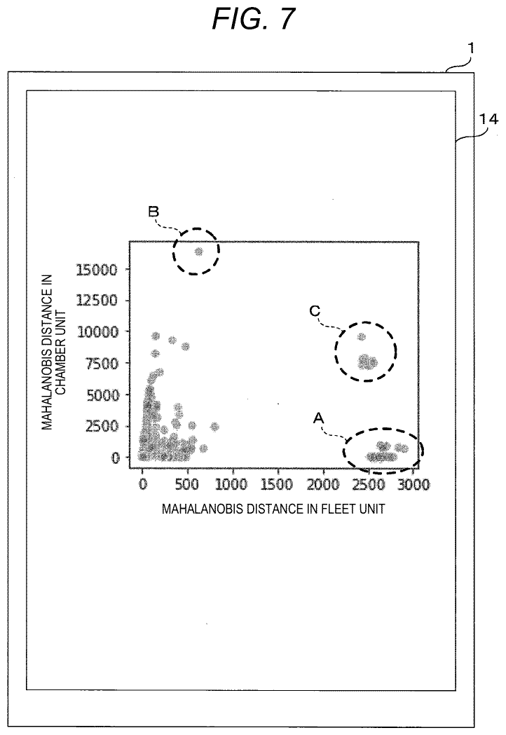

FIG. 7 is a schematic diagram illustrating an example of visualization of variations in a fleet unit and a chamber unit. In the illustrated example, a scattering diagram is displayed in which one monitoring data is plotted as one dot on the two-dimensional plane by representing a horizontal axis as a Mahalanobis distance in a fleet unit and a vertical axis as a Mahalanobis distance in a chamber unit. In the scattering diagram of the present example, the monitoring data having small variations in a fleet unit and a chamber unit is plotted in an area close to an origin at a lower left side of the scattering diagram. The monitoring data plotted in an area at a lower right side of the scattering diagram (see area A surrounded by a broken line) has large variations in a fleet unit and small variations in a chamber unit. The monitoring data plotted in an area at an upper left side of the scattering diagram (see area B surrounded by a broken line) has large variations in a chamber unit and small variations in a fleet unit. The monitoring data plotted in an area at an upper right side of the scattering diagram (see area C surrounded by a broken line) has large variations in both fleet unit and chamber unit.

Furthermore, the information processing apparatus 1 divides the plurality of monitoring data plotted on the two-dimensional plane into a plurality of monitoring data groups, based on the visualization results of variations in a fleet unit and a chamber unit. For example, in the scattering diagram illustrated in FIG. 7, three monitoring data groups of the areas A to C surrounded by a broken line and the monitoring data group based on other monitoring data not surrounded by a broken line can be divided into the four monitoring data groups. The division into the plurality of monitoring data groups may be automatically performed by the information processing apparatus 1 based on a predetermined division rule, for example, or may be performed by the information processing apparatus 1 by receiving a selection operation of the user, for example.

The information processing apparatus 1 re-acquires the original monitoring data for each of the monitoring data groups, generates a dimensional compression model based on principal component analysis, for example, and performs dimensional compression of the monitoring data. The information processing apparatus 1 creates, for example, two-dimensional scattering diagrams for each monitoring data group using the monitoring data subjected to the dimensional compression, and displays the plurality of scattering diagrams side by side on the display 14.

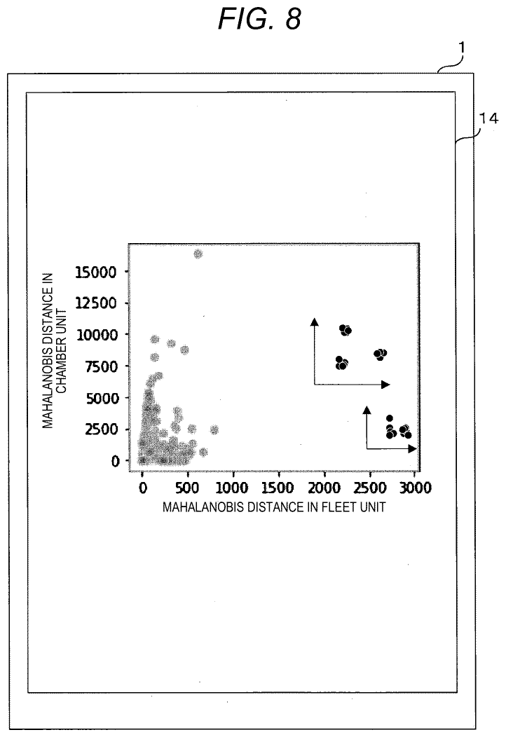

FIG. 8 is a schematic diagram illustrating an example of visualization of variations in a fleet unit and a chamber unit. In the example illustrated in FIG. 8, the monitoring data included in each of area A and area C in the example illustrated in FIG. 7 is defined as a monitoring data group, and the dimensional compression based on principal component analysis is performed again on the two monitoring data groups. In the example illustrated in FIG. 8, the information processing apparatus 1 creates scattering diagrams for the two monitoring data groups in which a horizontal axis and a vertical axis represent a first principal component and a second principal component selected through dimensional compression, respectively. The information processing apparatus 1 displays the scattering diagram created for each monitoring data group by disposing in an appropriate location on the scattering diagram of FIG. 7. In this case, the information processing apparatus 1 can display a scattering diagram of the monitoring data group corresponding to a position where each monitoring data group is displayed in the scattering diagram of FIG. 7, for example, a central position of the plurality of monitoring data included in the monitoring data group. However, when the display position of each scattering diagram is determined by the method, if there is a possibility that some or all of the plurality of scattering diagrams overlap with each other, the information processing apparatus 1 may adjust the position as appropriate so as to eliminate the overlap of the scattering diagrams.

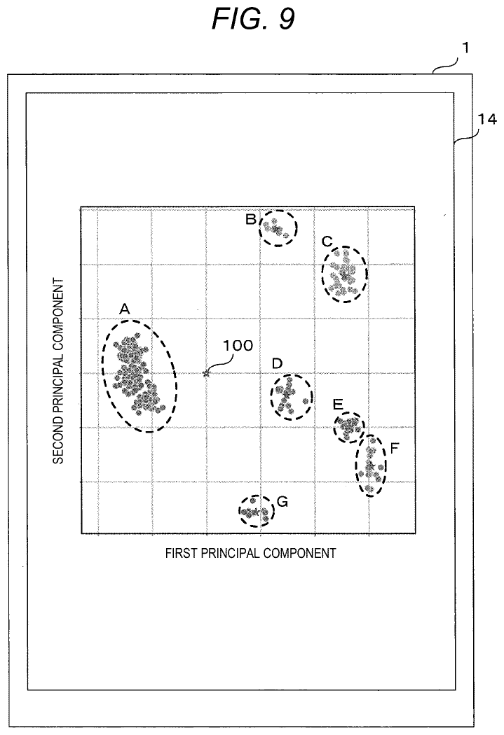

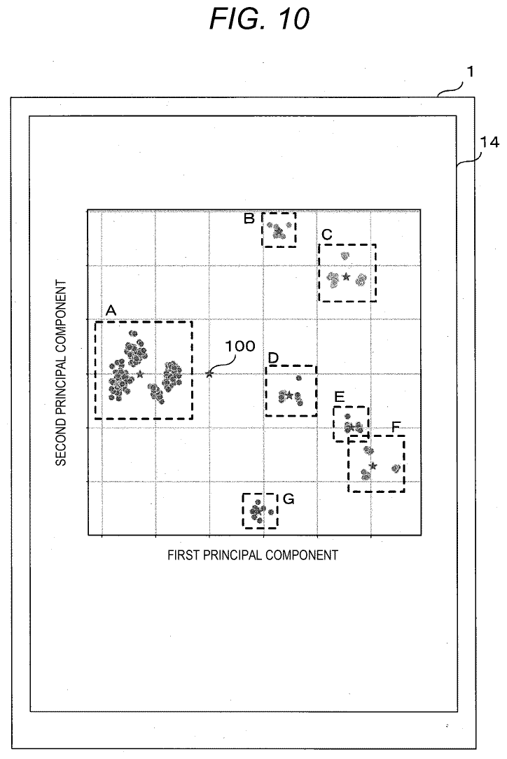

The information processing system according to the present embodiment can visualize variations in a fleet unit and a chamber unit based on principal component analysis, separately from the visualization of variations in a fleet unit and a chamber unit based on the Mahalanobis distance described above. FIGS. 9 and 10 are schematic diagrams illustrating an example of visualization of variations in a fleet unit and a chamber unit based on principal component analysis.

In the example illustrated in FIG. 9, the information processing apparatus 1 performs dimensional compression by principal component analysis on the monitoring data for all the chambers 3 of the fleet, thereby creating a scattering diagram in which a horizontal axis and a vertical axis represent a first principal component and a second principal component, respectively. In the scattering diagram of the present example, the plurality of monitoring data are divided into seven monitoring data groups A to G surrounded by a broken line. Each of the monitoring data groups A to G is represented as a plurality of dots representing the monitoring data belonging to the data group, and an asterisk representing the central position of distribution of the plurality of monitoring data. An asterisk 100 not included in any of the monitoring data groups A to G represents a central position of distributions of all the monitoring data.

The information processing apparatus 1 divides all the monitoring data into a plurality of monitoring data groups based on results of performing dimensional compression on the monitoring data about all the chambers 3 by principal component analysis. The division into the plurality of monitoring data groups may be automatically performed by the information processing apparatus 1 based on a predetermined division rule, for example, or may be performed by the information processing apparatus 1 by receiving a selection operation of the user, for example. The information processing apparatus 1 further performs dimensional compression for each group of the plurality of monitoring data group by principal component analysis.

In the example illustrated in FIG. 10, each of the monitoring data groups A to G in the example illustrated in FIG. 9 is individually subjected to dimensional compression by principal component analysis, and results of re-dimensional compression are shown in the original scattering diagram. For example, the information processing apparatus 1 acquires monitoring data of one monitoring data group A, performs dimensional compression, and creates a scattering diagram in which a horizontal axis and a vertical axis represent a new first principal component and second principal component obtained through the dimensional compression, respectively. For example, the information processing apparatus 1 displays the created scattering diagram on the original scattering diagram in an overlapping manner such that the central position of distribution of the created new scattering diagram coincides with the central position of distribution of the monitoring data group A corresponding to the original scattering diagram. In addition, the information processing apparatus 1 determines a size of the new scattering diagram and displays the new scattering diagram on the original scattering diagram in an overlapping manner such that a scale of the created new scattering diagram and a scale of the original scattering diagram coincide with each other. The information processing apparatus 1 performs dimensional compression and creation of scattering diagrams in the same manner for all the monitoring data groups A to G, and performs the display illustrated in FIG. 10.

The information processing system according to the present embodiment can visualize variations in a fleet unit and a chamber unit by at least one of a method using the Mahalanobis distance and a method using principal component analysis.

### (3) Visualization Process Based on Label Information

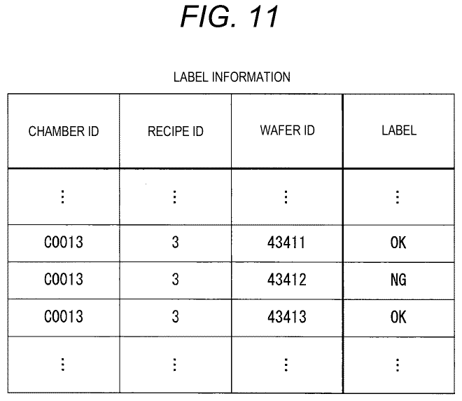

In the information processing system according to the present embodiment, for example, for each wafer processed by each chamber 3, the information processing apparatus 1 holds that the process for the wafer is possible or not (for example, OK/NG, non-defective products/defective products, or the like) as the label information. FIG. 11 is a schematic diagram illustrating an example of a configuration of the label information. The illustrated label information is information in which “chamber ID”, “recipe ID”, “wafer ID”, and “label” are associated with each other. The “chamber ID”, “recipe ID”, and “wafer ID” are the same as those included in the monitoring data illustrated in FIG. 3, and are information for associating the monitoring data with the label information. The “label” is a determination result of “OK (non-defective product)” or “NG (defective product)” for the wafer processed in the chamber 3.

The label information does not need to be assigned to all the monitoring data serving as a visualization target, and may be assigned to a part of the monitoring data. Whether the label information is assigned to the monitoring data can be determined based on the “flag” of the monitoring data illustrated in FIG. 3. The information processing system according to the present embodiment implements visualization capable of supporting the user to infer the label information of the monitoring data to which no label information is assigned, by using a part of the monitoring data to which label information is assigned, in a state where the label information is assigned to a part of the monitoring data.

The label information is information generated based on a determination result obtained by determining whether the process for the wafer is possible after the process is performed on the wafer by the chamber 3, for example, in a test process or the like. The label information may be input using the operator 15 of the information processing apparatus 1 by the user, for example, or may be generated by a test apparatus, for example. Further, the information processing apparatus 1 sets a predetermined value (for example, ‘1’) for the monitoring data to which the label information is assigned, to the “flag” illustrated in FIG. 11. In the present embodiment, the label information is managed separately from the monitoring data. However, for example, the monitoring data and the label information may be collectively managed by providing an item of the “label” in the monitoring data.

The information processing apparatus 1 of the present embodiment acquires the monitoring data stored in the monitoring data storage 12c, and the label information created in association with the monitoring data, and performs a visualization process for separating the monitoring data to which the “OK” label is assigned and the monitoring data to which the “NG” label is assigned. First, the information processing apparatus 1 generates a dimensional compression model for compressing dimensions of the monitoring data by a PCA method, based on the plurality of monitoring data read from the monitoring data storage 12c. The monitoring data used for the generation of the dimensional compression model may include a mixture of monitoring data to which the label information is assigned and monitoring information to which no label information is assigned. In the PCA method, for example, N principal components can be generated for N-dimensional data, and a degree of contribution (degree of importance) can be calculated for each principal component. The information processing apparatus 1 can perform dimensional compression of data by selecting a predetermined number (for example, two) of a principal component from among the N principal components having a high degree of contribution from the higher order.

In the visualization process based on the label information, the information processing apparatus 1 selects a predetermined number (for example, two) of principal components from the N principal components, and produces a combination of the two principal components. For example, when 100 principal components are present, and two principal components are selected from the 100 principal components to produce a combination, the information processing apparatus 1 can produce 4950 combinations. The information processing apparatus 1 selects, for example, some combinations of principal components having a high degree of contribution from the higher order from among the combinations of principal components thus produced, and generates a scattering diagram of monitoring data for each selected combination. For example, the information processing apparatus 1 distinguishes the monitoring data to which the “OK” label is assigned, the monitoring data to which the “NG” label is assigned, and the monitoring data to which no label is assigned, for example, by color classification, and displays the monitoring data in the scattering diagram. The information processing apparatus 1 displays, for example, a plurality of scattering diagrams corresponding to the plurality of combinations side by side on the display 14, thereby presenting the scattering diagrams to the user, and receives the selection of the scattering diagrams by the user, that is, the selection of the combination of the principal components. For example, the user selects a combination of the principal components for best separating the monitoring data, to which the “OK” label is assigned, and the monitoring data, to which the “NG” label is assigned, based on the plurality of scattering diagrams displayed. The information processing apparatus 1 adopts the selected set of principal components as a set of principal components used for visualization, and displays a scattering diagram in which the monitoring data is visualized using the set of principal components.

The method of selecting the combination of principal components described above is a method in which the user manually selects the combination of principal components. However, the information processing apparatus 1 may select the combination of principal components by performing predetermined arithmetic. The information processing apparatus 1 can select, for example, a combination of two principal components capable of best separating the OK and NG labels by using a method of multivariate variance analysis. When the combination of two principal components is selected, it is appropriate to perform variance analysis in a bivariate manner. For example, the information processing apparatus 1 calculates F-values by multivariate variance analysis for each combination of two principal components, and calculates F-values for all combinations (or some combinations with a high degree of contribution). By selecting the combination of principal components having the largest F-value, the information processing apparatus 1 can select the combination of two principal components for best separating the labels.

The F-value obtained by multivariate variance analysis can be calculated using, for example, Wilk's lambda and a degree of freedom. The Wilk's lambda is obtained by dividing a matrix formula of the sum of squares of errors from an average calculated for each label by a matrix formula of the sum of squares of errors from the overall average of the data. In addition to the Wilk's lambda, the F-value may be calculated from statistics such as a pillai trace, a hotelling trace, or a Roy's greatest root. Since the calculation of the F-value by multivariate variance analysis is an existing technique, a detailed description thereof will be omitted. In addition, the method of selecting a principal component by the information processing apparatus 1 is not limited to the method using the F-value of the multivariate variance analysis, and various existing methods may be used, such as a method using a regression coefficient of logistic regression, a Gini coefficient of random forest, or the like.

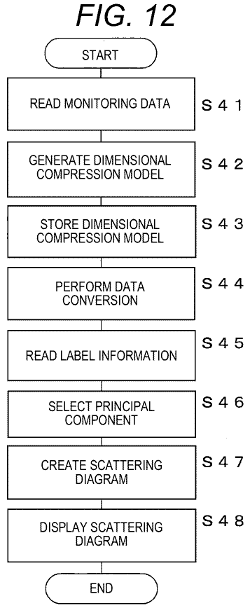

FIG. 12 is a flowchart illustrating an example of a procedure of a visualization process based on the label information, which is performed by the information processing apparatus 1 according to the first embodiment. The monitoring data acquirer 11b of the processor 11 of the information processing apparatus 1 according to the present embodiment reads the plurality of monitoring data stored in the monitoring data storage 12c of the storage 12 (step S41). Next, the dimensional compression model generator 11c of the processor 11 generates a dimensional compression model for compressing the number of dimensions of the monitoring data read in step S1, for example, by a method of principal component analysis (step S42). The dimensional compression model generator 11c stores the information related to the dimensional compression model generated in step S42 in the dimensional compression model information storage 12d of the storage 12 (step S43). The data converter 11d of the processor 11 inputs the monitoring data read in step S41 into the dimensional compression model generated in step S42, and performs data conversion on the monitoring data by acquiring the data output by the dimensional compression model (step S44).

Next, the processor 11 reads the label information that is created in advance and stored in the storage 12 (step S45). The processor 11 selects a combination of a predetermined number (for example, two) of principal components capable of best separating the monitoring data, to which a predetermined label (for example, NG label) is assigned, from monitoring data other than the monitoring data, from among the plurality of principal components included in the monitoring data that is data-converted, based on the monitoring data that is data-converted in step S44 and the label information read in step S45 (step S46). The selection of the principal component may be automatically performed, for example, by the information processing apparatus 1 as described above, or may be selected by the user, for example.

The display processor 11e of the processor 11 generates a scattering diagram in which the monitoring data that is data-converted in step S44 is visualized by combining the principal components selected in step S46 (step S47). The display processor 11e displays the scattering diagram generated in step S47 on the display 14 (step S48), and completes the process.

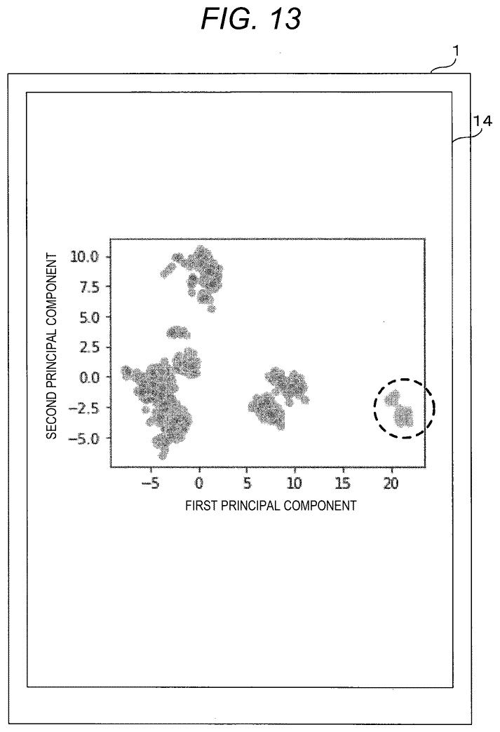

FIG. 13 is a schematic diagram illustrating an example of the visualization process based on the label information. In the illustrated example, the information processing apparatus 1 displays a scattering diagram in which the monitoring data is plotted on the two-dimensional plane by selecting appropriate two principal components from among the plurality of principal components obtained by the method of principal component analysis on the monitoring data, and representing a horizontal axis as a first principal component and a vertical axis as a second principal component. In addition, the information processing apparatus 1 plots, on the scattering diagram, the monitoring data with different color dots according to the flag assigned to each monitoring data, in the present example, the monitoring data, to which the OK flag is assigned, with dark colored dots, and the monitoring data, to which the NG flag is assigned, with light colored dots. In the illustrated scattering diagram, the monitoring data to which the NG flag is assigned is collected in an area on a right side (refer to an area surrounded by a broken line), and is separated from the monitoring data to which the OK flag is assigned.

In the present example, two types of labels assigned to the monitoring data are “OK” and “NG”. However, the present disclosure is not limited thereto, and three or more types of labels may be assigned to the monitoring data. In addition, the types of the label are not limited to “OK” and “NG”, and various other labels may be assigned to the monitoring data. For example, the information processing apparatus 1 can determine which one of a plurality of labels is focused on to select a principal component for separating the monitoring data by receiving an operation of selecting a label by the user.

### (4) Visualization Process Using Scale Conversion Based on Label Information

The information processing apparatus 1 of the present embodiment can perform scale conversion on a plurality of values (detection values of sensor) included in the monitoring data, convert each value into a value within, for example, the range from 0 to 1 or the range from −1 to 1, and generate a dimensional compression model using the scale-converted value. The information processing apparatus 1 can use, for example, a value obtained by extracting a minimum value and a maximum value from the plurality of values, and performing arithmetic of dividing a value obtained by subtracting the minimum value from the value by a difference between the maximum value and the minimum value, as the scale-converted value. This is a so-called minimum-maximum scale conversion method, and is a method of converting each value into a value within the range of 0 to 1. However, the scale conversion of the information processing apparatus 1 is not limited to the minimum-maximum scale conversion. For example, the information processing apparatus 1 may adopt various scaling conversion methods such as performing scale conversion such that the average value becomes 0 and the standard deviation becomes 1.

In the visualization process using scale conversion based on the label information, the information processing apparatus 1 extracts monitoring data to which a predetermined label (for example, an OK label) is assigned from among the monitoring data, and determines a scale conversion rule (for example, the minimum value and the maximum value in the minimum-maximum scale conversion) using only the monitoring data of the extracted predetermined label. The monitoring data to be visualized by the information processing apparatus 1 may be a mixture of monitoring data to which the label information is assigned and monitoring data to which no label information is assigned. The information processing apparatus 1 performs scale conversion of all the monitoring data using the scale conversion rule determined based on the monitoring data of the predetermined label.

Next, the information processing apparatus 1 generates a dimensional compression model using the scale-converted monitoring data. In this case, the information processing apparatus 1 may generate the dimensional compression model using, for example, only the monitoring data to which a predetermined label is assigned, or may generate the dimensional compression model using, for example, all the monitoring data regardless of the presence or absence of the label. The information processing apparatus 1 uses the generated dimensional compression model to convert all the monitoring data, thereby generating, for example, two-dimensional data for display, and displaying a graph such as a scattering diagram, based on the generated data for display.

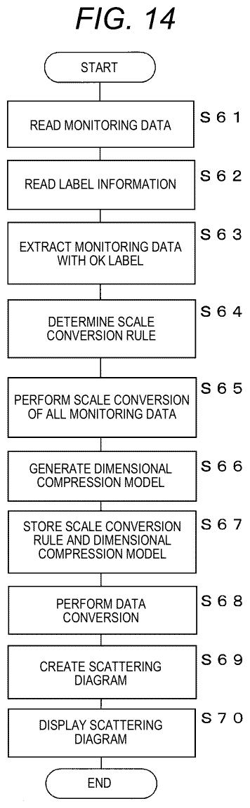

FIG. 14 is a flowchart illustrating an example of a procedure of a visualization process using scale conversion based on the label information, which is performed by the information processing apparatus 1 according to the first embodiment. The monitoring data acquirer 11b of the processor 11 of the information processing apparatus 1 according to the present embodiment reads the plurality of monitoring data stored in the monitoring data storage 12c of the storage 12 (step S61). In addition, the processor 11 reads the label information that is created in advance and stored in the storage 12 (step S62).

The processor 11 extracts monitoring data to which a predetermined label (for example, the OK label) is assigned from among the monitoring data read in step S61, based on the label information read in step S62 (step S63). The processor 11 determines a scale conversion rule based on the monitoring data extracted in step S63 (step S64). The processor 11 performs scale conversion on all the monitoring data read in step S61 based on the rule determined in step S64 (step S65).

Next, the dimensional compression model generator 11c of the processor 11 generates a dimensional compression model for compressing the number of dimensions of the monitoring data that is scale-converted in step S64 (step S66). The dimensional compression model generator 11c may generate the dimensional compression model using only the monitoring data to which a predetermined label is assigned, or may generate the dimensional compression model using all the monitoring data. The processor 11 stores the scale conversion rule determined in step S64 and the information related to the dimensional compression model generated in step S66 in the dimensional compression model information storage 12d of the storage 12 (step S67). The data converter 11d of the processor 11 inputs the monitoring data scale-converted in step S64 into the dimensional compression model generated in step S66, and performs data conversion on the monitoring data by acquiring the data output by the dimensional compression model (step S68). The display processor 11e of the processor 11 generates a scattering diagram in which the monitoring data that is data-converted in step S68 is visualized (step S69). The display processor 11e displays the scattering diagram generated in step S69 on the display 14 (step S70), and completes the process.

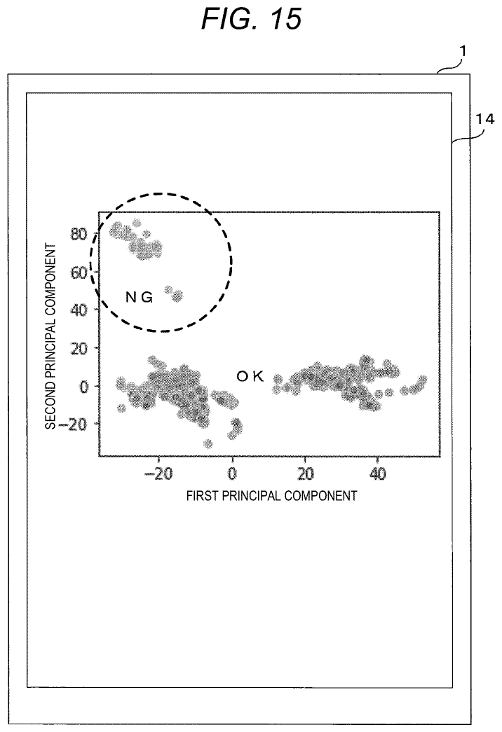

FIG. 15 is a schematic diagram illustrating an example of the visualization process using scale conversion based on the label information. In the illustrated example, the information processing apparatus 1 displays a scattering diagram in which the monitoring data is plotted on the two-dimensional plane by determining the scale conversion rule based on the monitoring data to which the OK label is assigned, scale-converting all the monitoring data, two-dimensionally compressing the monitoring data by a method of principal component analysis, and representing a horizontal axis as a first principal component and a vertical axis as a second principal component. In addition, the information processing apparatus 1 plots, on the scattering diagram, the monitoring data with different color dots according to the flag assigned to each monitoring data, in the present example, the monitoring data, to which the OK flag is assigned, with dark colored dots, and the monitoring data, to which the NG flag is assigned, with light colored dots. In the illustrated scattering diagram, the monitoring data to which the NG flag is assigned is collected in an area on an upper side (refer to an area surrounded by a broken line), and is separated from the monitoring data to which the OK flag is assigned.

### (5) Visualization Process Using Autoencoder

The information processing apparatus 1 according to the present embodiment generates an autoencoder (self-encoder) by performing a machine learning process using, for example, monitoring data to which the OK label is assigned. The autoencoder is a learning model in which an encoder that converts input data into low-dimensional data is combined with a decoder that converts the low-dimensional data into original data. Since the autoencoder is an existing technique, a detailed description of the process of generating the autoencoder will be omitted. The autoencoder generated using the monitoring data with the OK label can convert the input monitoring data with the OK label into low-dimensional data, and restore the low-dimensional data to original monitoring data. However, the autoencoder generated using the monitoring data with the OK label can convert the input monitoring data with the NG label into low-dimensional data, and cannot restore the low-dimensional data to original monitoring data.

The information processing apparatus 1 of the present embodiment inputs all the monitoring data, which include the monitoring data, to which the OK and NG labels are assigned, and the monitoring data to which no label is assigned, into the autoencoder generated using the monitoring data with the OK label, and acquires data that is output by the autoencoder. The information processing apparatus 1 calculates a difference between the data input into the autoencoder and the data output by the autoencoder with respect to each monitoring data. The calculated difference is data having the same dimensions as the monitoring data. The information processing apparatus 1 performs a process, such as the generation and visualization of the dimensional compression model, on the differential data calculated for each monitoring data.

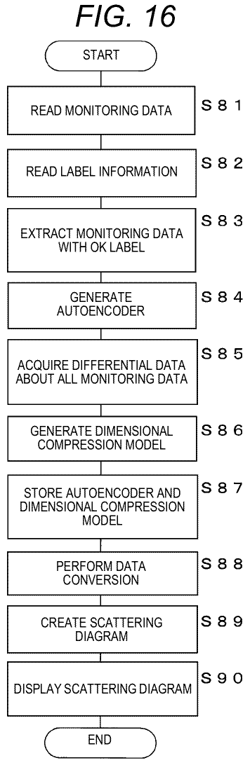

FIG. 16 is a flowchart illustrating an example of a procedure of a visualization process using an autoencoder, which is performed by the information processing apparatus 1 according to the first embodiment. The monitoring data acquirer 11b of the processor 11 of the information processing apparatus 1 according to the present embodiment reads the plurality of monitoring data stored in the monitoring data storage 12c of the storage 12 (step S81). In addition, the processor 11 reads the label information that is created in advance and stored in the storage 12 (step S82).

The processor 11 extracts monitoring data to which a predetermined label (for example, the OK label) is assigned from among the monitoring data read in step S81, based on the label information read in step S82 (step S83). The processor 11 uses the monitoring data of the OK label extracted in step S83 to perform a machine learning process, thereby generating an autoencoder (step S84). For all the monitoring data read in step S81, the processor 11 inputs the monitoring data into the autoencoder generated in step S84, and acquires differential data by calculating the difference between the monitoring data and the data output by the autoencoder (step S85).

Next, the dimensional compression model generator 11c of the processor 11 generates a dimensional compression model for compressing the number of dimensions of the differential data that is acquired in step S85 (step S86). The processor 11 stores information related to the autoencoder generated in step S84 and the dimensional compression model generated in step S86 in the dimensional compression model information storage 12d of the storage 12 (step S87).

The data converter 11d of the processor 11 inputs the differential data acquired in step S85 into the dimensional compression model generated in step S86, and performs data conversion of the differential data by acquiring the data output by the dimensional compression model (step S88). The display processor 11e of the processor 11 generates a scattering diagram in which the differential data that is data-converted in step S88 is visualized (step S89). The display processor 11e displays the scattering diagram generated in step S89 on the display 14 (step S90), and completes the process.

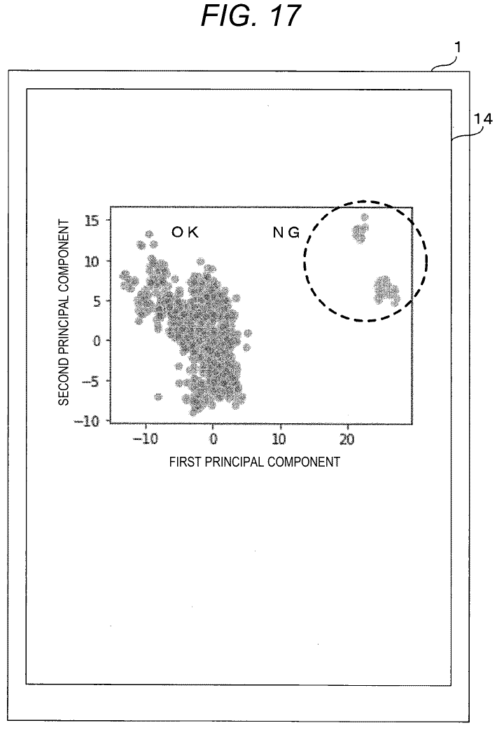

FIG. 17 is a schematic diagram illustrating an example of the visualization process using the autoencoder. In the illustrated example, the information processing apparatus 1 generates an autoencoder by machine learning using the monitoring data to which the OK label is assigned, acquires differential data between input and output of the autoencoder for all the monitoring data, and displays a scattering diagram in which the differential data is dimensionally compressed and plotted on the two-dimensional plane. In addition, the information processing apparatus 1 plots, on the scattering diagram, the differential data, which corresponds to the monitoring data to which the OK flag is assigned, with dark colored dots, and the differential data, which corresponds to the monitoring data to which the NG flag is assigned, with light colored dots, depending on the flag assigned to the monitoring data corresponding to each differential data. In the illustrated scattering diagram, the monitoring data to which the NG flag is assigned is collected in an area on an upper right side (refer to an area surrounded by a broken line), and is separated from the monitoring data to which the OK flag is assigned.

As described above, the information processing apparatus 1 according to the present embodiment can present a large amount of multi-dimensional monitoring data in a two-dimensional or three-dimensional graph that can be easily grasped by the user by performing the visualization process of the monitoring data according to (1) to (5) described above. Thus, the user can expect to verify factors, causes, or the like such as malfunctions and individual differences of the plurality of chambers 3 from a graph such as a scattering diagram displayed on the display 14 of the information processing apparatus 1.

The information processing apparatus 1 according to the present embodiment does not need to perform all of the above-described visualization processes (1) to (5), and may perform at least one of the visualization processes (1) to (5). Further, in the present embodiment, an example in which a two-dimensional scattering diagram is displayed as a result of the visualization of the monitoring data has been described. However, the present disclosure is not limited thereto. The information processing apparatus 1 may visualize the monitoring data by using a graph other than the scattering diagram, for example, a histogram, a box and whisker plot, a violin chart, a swarm plot, a scattering diagram, a density contour diagram, or a heat map.

### <Chamber Verification Process>

In the information processing system according to the present embodiment, the information processing apparatus 1 stores and accumulates the monitoring data acquired from the plurality of chambers 3 in a database, converts the accumulated monitoring data into low-dimensional data, and displays a graph such as a scattering diagram. For example, in order to use the function such as the visualization of the monitoring data by the information processing system according to the present embodiment, a user such as an administrator or a worker of a semiconductor manufacturing factory needs to make settings in advance, such as information related to a fleet (the plurality of chambers 3) that is a monitoring target, a type of information to be collected as the monitoring data, and an acquisition timing of the information to be collected, in the information processing apparatus 1. The information processing apparatus 1 that receives the settings from the user acquires necessary information from the chamber 3 and accumulates the necessary information in the database when various processes are performed on the wafer by the chamber 3.

After the process of the chamber 3 is performed for a predetermined period of time, and a sufficient amount of monitoring data is accumulated in the database, the user causes the information processing apparatus 1 to perform the above-described visualization process so that factors, causes, or the like such as malfunctions and individual differences for the plurality of chambers 3, which are monitoring targets, can be verified based on various graphs displayed on the display 14. For example, the user can specify factors of an abnormality or the like (which sensor detects the abnormality or the like) of the chamber 3 in which the abnormality or the like has occurred, based on the displayed graph such as a scattering diagram. In addition, for example, the user assigns some labels to each monitoring data based on the displayed graph such as a scattering diagram, and performs so-called supervised machine learning process using the monitoring data to which the label is assigned, so that it is possible to generate a learning model that infers the presence or absence of the abnormality, a degree of deterioration of the chamber 3, or the like based on the input monitoring data, for example. Further, the user can verify, for example, which sensor has a high degree of importance for detection of an abnormality or the like in the chamber 3, based on the generated learning model.

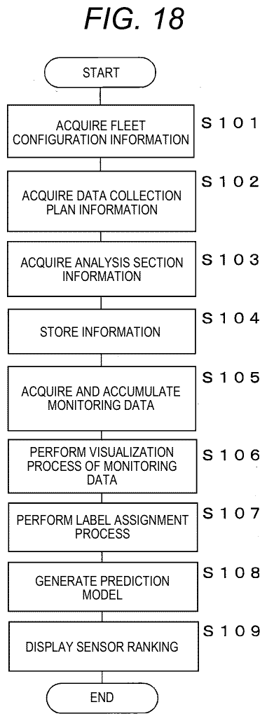

FIG. 18 is a flowchart illustrating a procedure of a chamber verification process performed by the information processing system according to the present embodiment. The processor 11 of the information processing apparatus 1 according to the present embodiment receives an input of information by the user through the operator 15, thereby acquiring fleet configuration information (step S101). The fleet configuration information includes, for example, a fleet ID assigned to the fleet, the number, type, and chamber ID of the chambers 3 included in the fleet, the number and type of sensors installed in each chamber 3, and information such as contents and setting values of the process performed in each chamber 3.

Next, the processor 11 receives the input of information by the user through the operator 15, thereby acquiring data collection plan information (step S102). The data collection plan information sets conditions for data to be collected by the information processing apparatus 1 as monitoring data, and is information designating, for example, a recipe ID of a recipe to be collected, a recipe step ID of a recipe step, a type of statistical values, a type of sensors, and the like.

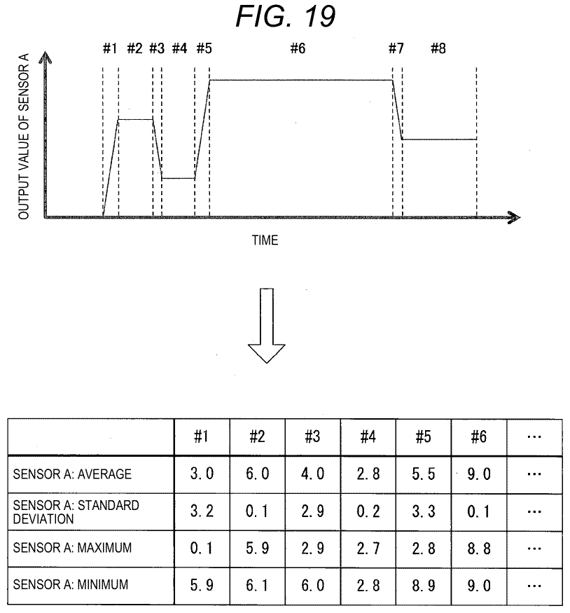

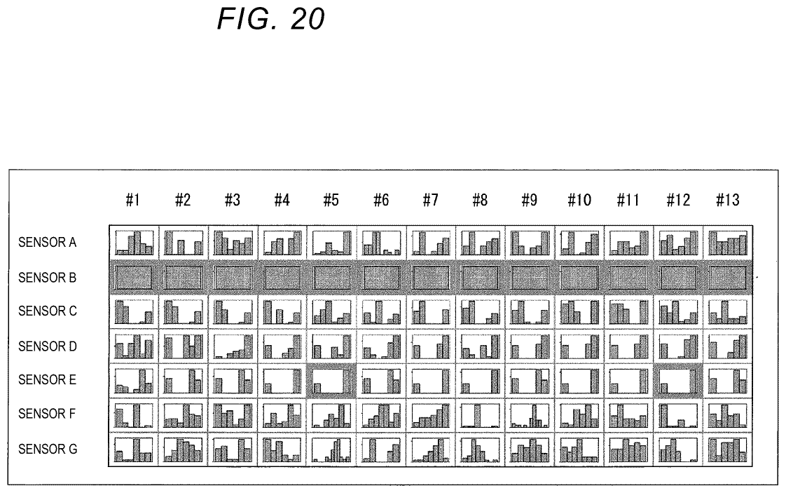

FIGS. 19 and 20 are schematic diagrams for explaining an example of the data collection plan information. The upper part of FIG. 19 illustrates, as a graph, an example of a temporal change in a value output by a sensor A installed in the chamber 3 when a predetermined process is performed on one wafer. The information processing apparatus 1 may acquire time series data of output values from the sensor A by actually operating the chamber 3, for example, and display the illustrated graph on the display 14 based on the acquired output values to present the time series data to the user. In the present embodiment, a series of processes performed on one wafer by the chamber 3 can be divided into a plurality of recipe steps. In the present example, for example, as in a case where the recipe step having the recipe step ID “1” is described as “recipe step #1”, each recipe step is specifically described according to a rule of “recipe step”+“#”+“recipe step ID”. For example, the recipe step may be predetermined by a user such as a designer or administrator of the system and defined in the recipe. In addition, when the plurality of sensors are installed in the chamber 3, the time series data corresponding to the recipe step is similarly acquired for each sensor. The information processing apparatus 1 calculates statistical values such as the average, standard deviation, maximum, and/or minimum of the output values from the sensor A for each recipe step, based on the time series data of the output values from the sensor A acquired from the chamber 3 (see the lower part of FIG. 19).

For example, the information processing apparatus 1 acquires output values for the plurality of sensors in the plurality of chambers 3, similarly calculates statistical values, creates a histogram of the statistical values, and displays a list on the display 14 (see FIG. 20). In the illustrated example, as for seven sensors A to G provided in each chamber 3, statistical values (in the present example, average values) of output values in a plurality of recipe steps #1 to #13 are displayed as histograms that are arranged vertically and horizontally in a matrix. Based on the display, the user can select, for example, a combination of a recipe step and a sensor that varies considerably as an analysis target, and can exclude, for example, a combination of a step and a sensor that does not vary from an analysis target. For example, the user performs an operation of selecting one or more recipe steps for each sensor by performing an operation of selecting the displayed histogram on the operator 15. Each recipe step selected by the user is a data collection target, and the information processing apparatus 1 stores statistical values of the time series data of the selected recipe step of each sensor in each chamber 3 as monitoring data. In the present example, the average value is used as the statistical value of each sensor. However, for example, the display may be changed to each statistical value of the standard deviation, the maximum value, or the minimum value according to the selection of the user. The plurality of recipe steps and a plurality of types of statistical values may be selected by the user for one sensor, and in the present embodiment, the information processing apparatus 1 stores data with different types of recipe steps or statistical values even for the same sensor in the monitoring data storage 12c as different monitoring data.

Next, the processor 11 receives the input of information by the user through the operator 15, thereby acquiring analysis section information (step S103). The analysis section information is information related to a period (data scope) serving as an analysis target. The processor 11 stores, in the storage 12, the fleet configuration information acquired in step S101, the data collection plan information acquired in step S102, and the analysis section information acquired in step S103 (step S104). The control processor 11a of the processor 11 operates the chamber 3 to perform the process on wafers at a preset process date and time, and the monitoring data acquirer 11b of the processor 11 acquires and accumulates detection values detected by the sensors in the chamber 3 as monitoring data (step S105).

Next, the processor 11 performs a process of visualizing the monitoring data stored in the monitoring data storage 12c, for example, in response to a request from the user (step S106). In step S106, at least one of the visualization processes using the above-described methods (1) to (5) is performed. Which visualization process is to be performed are based on the selection of the user, for example.

Next, the processor 11 receives the input of information by the user through the operator 15, thereby performing a label assignment process on the monitoring data (step S107). For example, the processor 11 displays a scattering diagram in which the monitoring data is visualized on the display 14, receives a selection of one or more dots from among a plurality of dots included in the scattering diagram from the user, and receives an input of a label for the selected one or more dots. The processor 11 stores the label input by the user in association with the monitoring data corresponding to the dots displayed in the scattering diagram. The label assigned in step S107 is used in the next step S108. However, the label information may be used as the label information for the visualization process illustrated in FIG. 11.

Next, the processor 11 uses the monitoring data, to which the label is assigned in step S107, to perform a so-called supervised machine learning process to receive the monitoring data as an input, thereby performing a process of generating a prediction model for predicting the label of the monitoring data (step S108). As the prediction model, for example, a learning model of various configurations such as support vector machine (SVM), random forest, logistic regression, linear discriminant analysis, gradient boosting, or neural network may be adopted. Since the supervised machine learning process is an existing technique, a detailed description thereof will be omitted.

Next, the processor 11 displays a sensor ranking related to the plurality of sensors installed in the chamber 3 on the display 14 based on the prediction model generated in step S108 (step S109), and completes the process. The sensor ranking is information in which the plurality of sensors installed in the chamber 3 are arranged in order of the degree of importance, representing which sensors have a high degree of importance (degree of contribution) to predictions of the prediction model.

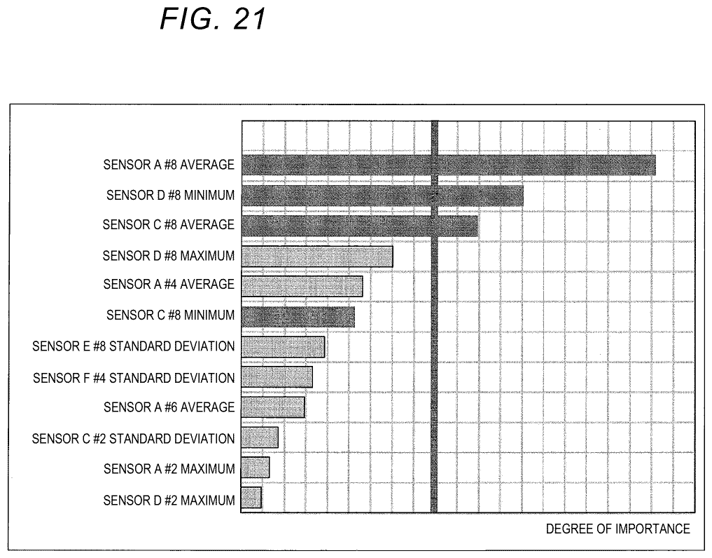

FIG. 21 is a schematic diagram illustrating an example of sensor ranking. The sensor rankings illustrated in FIG. 21 are represented by a horizontal bar graph illustrating the degree of importance of the sensors included in the monitoring data, and are displayed side by side from a top to a bottom in descending order of the degree of importance. In the present example, each sensor serving as a calculation target of the degree of importance is distinguished by a combination of the sensor, period, and type of statistical values, and the degree of importance is calculated as different values for the same sensor when the periods or statistical values are different. However, this is merely an example, and when a plurality of combinations for one sensor is included in the monitoring data, the maximum value or average value of the degree of importance for each sensor may be acquired as a representative value from the degree of importance calculated for each combination of the sensor, period, and type of statistical values, for example, and the sensor ranking may be displayed such that one sensor represents one degree of importance based on the representative value.

The user selects one or more sensors from the displayed sensor ranking, and the information processing apparatus 1 receives the selection of the user. In the illustrated example, the user selects four items “sensor A, period #8, average”, “sensor D, period #8, minimum”, “sensor C, period #8, average”, and “sensor C, period #8, minimum” which represent the dark bar graphs. The information processing apparatus 1 can display, for example, a trend chart of time series detection values for the sensors selected by the user. In order to perform the graph display, the information processing apparatus 1 may store data of the time series detection values of the sensor, separately from the statistical values of the monitoring data. Further, the information processing apparatus 1 may perform a graph display for the sensor selected by the user, such as a scattering diagram in which the monitoring data is dimensionally compressed, for example.

When a learning model having a decision tree structure, such as random forest or gradient boosting, is used as the prediction model, the information processing apparatus 1 can calculate the degree of importance of input information, for example, for a prediction model having a decision tree structure, by examining which input information is used in branching conditions of the decision tree and a frequency used in the branching conditions of the input information. However, the configuration of the prediction model is not limited to the decision tree, and may be, for example, a configuration of a support vector machine (SVM), a neural network, or the like, and in this case, the degree of importance of the input information can be calculated using, for example, an explainable artificial intelligence (XAI) technique such as local interpretable model-agnostic explanations (LIME) or shapley additive explanations (SHAP). Further, for example, the prediction model may be a transformer or the like, and in this case, the degree of importance of the input information may be calculated using, for example, an attention mechanism. Since the calculation of the degree of importance of the input information to the prediction model is an existing technique, a detailed description thereof will be omitted.

### SUMMARY

In the information processing system according to the present embodiment configured as described above, the information processing apparatus 1 acquires monitoring data which includes a plurality of items related to a state of each process performed by the chamber (target apparatus) 3. The information processing apparatus 1 generates a dimensional compression model for compressing the number of dimensions of the monitoring data, inputs the monitoring data into the dimensional compression model to convert the monitoring data into a low-dimensional representation, and displays (outputs) the monitoring data converted into the low-dimensional representation on the display 14. Thus, the information processing system according to the present embodiment can convert the multi-dimensional monitoring data into the low-dimensional representation to present to the user, so that it is possible to support analysis of the monitoring data obtained from the chamber 3.

In addition, in the information processing system according to the present embodiment, the monitoring data includes a plurality of items classified into a plurality of categories such as a pressure category and a temperature category, for example. The information processing apparatus 1 generates a dimensional compression model for each category included in the monitoring data, converts and displays the monitoring data into a low-dimensional representation for each category. Thus, the information processing system according to the present embodiment can visualize the monitoring data for each category and present the monitoring data to the user. Therefore, the information processing system can support, for example, verification of which category the factors or causes of malfunctions or individual differences in the chamber 3 are based on.

In addition, in the information processing system according to the present embodiment, the information processing apparatus 1 acquires the monitoring data about a plurality of chambers 3. The information processing apparatus 1 calculates a first distance of each monitoring data about a monitoring data group of the plurality of chambers 3 (fleets), and calculates a second distance of each monitoring data about the monitoring data group of each chamber 3. The information processing apparatus 1 converts and displays the monitoring data into a low-dimensional representation in which the calculated first distance and second distance are represented as dimensions. As the first distance and the second distance, for example, a Mahalanobis distance may be adopted. Thus, the information processing system according to the present embodiment can support the user in verifying whether variations in the monitoring data are in a fleet unit or a chamber unit.

Further, in the information processing system according to the present embodiment, a label related to the class classification is assigned to a part of the monitoring data stored in the information processing apparatus 1 in advance. The information processing apparatus 1 acquires label information assigned to the monitoring data, selects a predetermined number of dimensions based on the label information about the monitoring data converted into the low-dimensional representation by the dimensional compression model, and displays the monitoring data in the selected dimensions. Thus, the information processing system according to the present embodiment can support the user in verifying which dimension is effective for classifying the class of the monitoring data.

In addition, in the information processing system according to the present embodiment, the information processing apparatus 1 acquires the label information assigned to a part of the monitoring data. The information processing apparatus 1 determines references for scale conversion based on the monitoring data classified as a predetermined class by the label information, and performs scale conversion of the monitoring data of the predetermined class and a class other than the predetermined class based on the determined references. The information processing apparatus 1 generates a dimensional compression model based on the scale-converted monitoring data, and displays the dimensionally compressed monitoring data. Thus, the information processing system according to the present embodiment can display a scattering diagram or the like in which the monitoring data of the predetermined class may be separated from the monitoring data of the class other than the predetermined class.

In addition, in the information processing system according to the present embodiment, the information processing apparatus 1 acquires the label information assigned to a part of the monitoring data, and generates an autoencoder (self-encoder) based on the monitoring data that is classified as the predetermined class using the label information. The information processing apparatus 1 inputs the monitoring data of the predetermined class, the monitoring data of the class other than the predetermined class, and the monitoring data assigned with a label into the autoencoder, and calculates differential data between the input and the output of the autoencoder. The information processing apparatus 1 generates a dimensional compression model for compressing the number of dimensions of the differential data, and displays the dimensionally compressed differential data. Thus, the information processing system according to the present embodiment can display a scattering diagram or the like in which the monitoring data of the predetermined class may be separated from the monitoring data of the class other than the predetermined class.

In addition, in the information processing system according to the present embodiment, a label is assigned to a part of the monitoring data converted into the low-dimensional representation, and the information processing apparatus 1 generates a prediction model for predicting a label for the input of the monitoring data based on the monitoring data to which the label is assigned. Thus, the information processing system can predict results of the process performed by the chamber 3 using, for example, the monitoring data acquired during subsequent process of the chamber 3 and the generated prediction model.

In addition, in the information processing system according to the present embodiment, the information processing apparatus 1 calculates a degree of importance of the plurality of items included in the monitoring data based on the generated prediction model, and displays rankings of the plurality of items based on the calculated degree of importance. The information processing apparatus 1 receives the selection of the user based on the displayed degree of importance, thereby selecting a predetermined number of items from the plurality of items included in the monitoring data, and visualizing the monitoring data, time series data, or the like using the selected items. Thus, the user can perform analysis or the like with priority given to an item having a high degree of importance.

In addition, in the information processing system according to the present embodiment, the information processing apparatus 1 acquires detection values detected by the sensors in the chamber 3 as time series data, divides the process performed by the chamber 3 into a plurality of periods, and calculates statistical values of the time series data in each period. The information processing apparatus 1 displays a graph such as a histogram of each period based on the calculated statistical values, and receives a selection of a period, which serves as a monitoring target, from the user from the plurality of periods. The information processing apparatus 1 sets the received period as a period of the monitoring target of the chamber 3, calculates statistical values for each period of the monitoring target with respect to a value output by the sensor of the chamber 3, and stores the calculated statistical values as the monitoring data. Thus, the information processing apparatus 1 can select and store information useful for monitoring, from among a large amount of information that can be acquired from the sensor in the chamber 3.

In addition, in the information processing system according to the present embodiment, it is preferable for the information processing apparatus 1 to monitor and analyze a process, such as a substrate (wafer) processing process, a substrate transfer process, a wafer-less dry cleaning process, a seasoning process, a plasma health check process, or a sensor automatic check process, performed by the target apparatus such as the chamber 3 or the like.

In addition, in the information processing system according to the present embodiment, it is preferable that when the monitoring data is dimensionally compressed to output the monitoring data, the output is performed using, for example, a scattering diagram, a histogram, a box and whisker plot, a violin chart, a density contour diagram or a heat map.

### Second Embodiment

The information processing system according to the first embodiment is a system in which the information processing apparatus 1 performs a process such as the generation of the dimensional compression model based on the monitoring data acquired from the plurality of chambers 3, and performs the visualization process of the monitoring data to analyze malfunctions, individual differences, or the like in the chamber 3. In contrast, an information processing system according to a second embodiment is a system that analyzes one or more newly added chambers 3, for example, using analysis results related to the existing chamber 3. In the second embodiment, various types of information related to the analysis results of the existing chamber 3 will be referred to as analysis information.

The analysis information used by the information processing system according to the second embodiment may include, for example, the following information collected or generated in the information processing system according to the first embodiment.
Monitoring data stored in the monitoring data storage 12c
Dimensional compression model for each category stored in step S4 of FIG. 4
Covariance matrix stored in step S30 of FIG. 6
Label information illustrated in FIG. 11
Dimensional compression model stored in step S43 of FIG. 12
Scale conversion rule and dimensional compression model stored in step S67 of FIG. 14
Autoencoder and dimensional compression model stored in step S87 of FIG. 16
Fleet configuration information and data collection plan information stored in step S104 of FIG. 18

In addition, the analysis information used by the information processing system according to the second embodiment may include the following information.
Statistics on the Mahalanobis distance of the monitoring data in a fleet unit
Statistics on the monitoring data for each sensor in a fleet unit
Statistics on the Mahalanobis distance of the monitoring data in a chamber unit
Statistics on the monitoring data for each sensor in a chamber unit

However, the information processing apparatus 1 can generate or calculate a dimensional compression model, statistics, and the like based on the monitoring data. Therefore, the analysis information does not include information such as the dimensional compression model and statistics, and the information processing apparatus 1 may generate or calculate the dimensional compression model and the statistics based on the monitoring data included in the analysis information. Further, when the analysis information includes the dimensional compression model, the statistics, and the like, the monitoring data may not be included in the analysis information.

The monitoring data in a fleet unit refers to all the monitoring data acquired from all the chambers 3 included in a fleet (data about statistics collected based on a data collection plan). The information processing apparatus 1 calculates a covariance matrix based on all the monitoring data of all the chambers 3 serving as a target, and calculates a Mahalanobis distance of each monitoring data based on the calculated covariance matrix. A value such as average, variance (standard deviation), skewness, or kurtosis may be adopted for the statistics. In the present embodiment, an average value is used as the statistics. However, the present disclosure is not limited thereto, and various values may be adopted for the statistics. Further, the Mahalanobis distance may be a Mahalanobis distance calculated based on monitoring data that is subjected to dimensional compression by a dimensional compression model. The information processing apparatus 1 calculates the average value of the Mahalanobis distance calculated for each monitoring data, and stores the average value in the analysis information as “statistics of the Mahalanobis distance of the monitoring data in a fleet unit”.

The monitoring data for each sensor in a fleet unit is monitoring data obtained for each sensor installed in all of the chambers 3 included in the fleet. For example, when the monitoring data includes detection values of N sensors, a recipe step is a P-step, and Q-type values are stored as statistical values, all the monitoring data acquired from all the chambers 3 are divided into (N×P×Q) monitoring data groups. The information processing apparatus 1 stores the (N×P×Q) monitoring data groups in the analysis information as “statistics of all the monitoring data acquired from all the chambers 3”.

The monitoring data in a chamber unit is monitoring data acquired from each chamber 3, and when the fleet includes M chambers 3, the monitoring data group is M monitoring data groups. The information processing apparatus 1 calculates a covariance matrix from the monitoring data for each chamber 3, and calculates a Mahalanobis distance of each monitoring data of the chamber 3 based on the calculated covariance matrix. The information processing apparatus 1 stores the Mahalanobis distance calculated for each chamber 3 in the analysis information as “statistics of the Mahalanobis distance of the monitoring data in a chamber unit”.

The monitoring data for each sensor in a chamber unit is monitoring data obtained by dividing the monitoring data, which is acquired from each chamber 3, for each sensor installed in each chamber 3. For example, when L chambers 3 are included in the fleet, detection values of N sensors are included in the monitoring data, a recipe step is a P-step, and Q-type values are stored as statistical values, the monitoring data is divided into (L×N×P×Q) monitoring data groups. The information processing apparatus 1 stores the (L×N×P×Q) monitoring data groups in the analysis information as “statistics of the monitoring data for each sensor in a chamber unit”.

The “statistics of the monitoring data for each sensor in a chamber unit” and the above-described “statistics of all the monitoring data acquired from all the chambers 3” are different from each other in classifying and treating of the information obtained from all the chambers 3, and are substantially the same content information. The information processing apparatus 1 may store information obtained from all the chambers 3, and use the information as “statistics of the monitoring data for each sensor in a chamber unit” or “statistics of all the monitoring data acquired from all the chambers 3” as appropriate.

The monitoring data used for calculation of the statistics is preferably monitoring data acquired from the chamber 3 in which no malfunction or the like has occurred. Thus, the statistics can be used as a reference for determining that the chamber 3 is a normal chamber. In addition, the analysis information used by the information processing system according to the second embodiment does not need to include all the information described above, and may include at least one of the plurality of information described above.

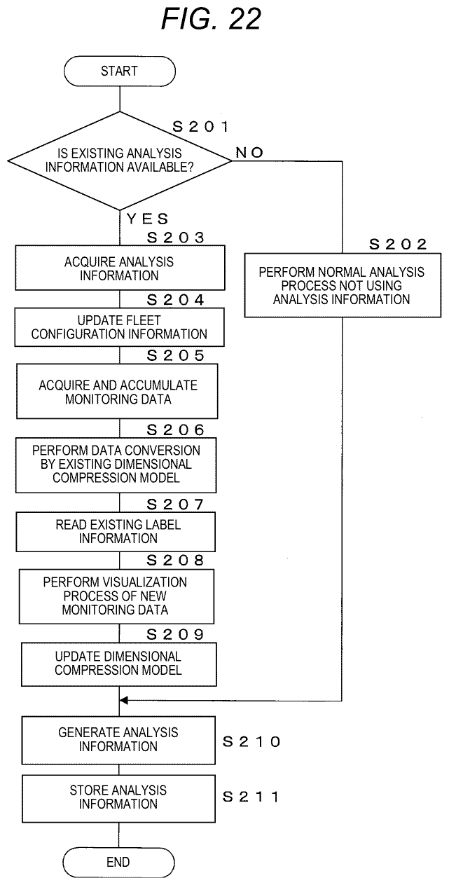

FIG. 22 is a flowchart for explaining an outline of an analysis process performed by the information processing apparatus 1 according to the second embodiment. The processor 11 of the information processing apparatus 1 according to the second embodiment determines whether the analysis information related to the existing chamber 3 can be used based on whether the analysis information is stored in the storage 12, for example (step S201). When the existing analysis information is not available (S201: NO), the processor 11 performs a normal analysis process that does not use the analysis information, for example, the process illustrated in FIG. 18 in the first embodiment (step S202), and the process proceeds to step S210.

When the existing analysis information is available (S201: YES), the processor 11 reads and acquires the analysis information from the storage 12 (step S203). For example, the processor 11 receives an input of information related to a chamber 3 that has been newly added or the like from the user, thereby updating information of a plurality of chambers 3 serving as a monitoring target, that is, configuration information of the fleet (step S204). Thereafter, the processor 11 causes the control processor 11a to operate the chamber 3 and performs the process on the wafer, and the monitoring data acquirer 11b acquires and accumulates detection values of the sensor in the chamber 3 as monitoring data (step S205).

After the monitoring data is accumulated, the processor 11 uses the existing dimensional compression model included in the analysis information acquired in step S203 to perform data conversion, that is, dimensional compression, of the monitoring data accumulated in step S205 (step S206). Further, the processor 11 reads existing label information included in the analysis information acquired in step S203 (step S207). The processor 11 performs a visualization process on new monitoring data accumulated in step S205 based on the results of the data conversion in step S206 and the label information read in step S207 (step S208). In step S208, at least one of (1) visualization process for each category, (2) visualization process for variations in a fleet unit and a chamber unit, (3) visualization process based on label information, (4) visualization process using scale conversion based on label information, and (5) visualization process using autoencoder described in the first embodiment is performed.

The processor 11 uses the new monitoring data accumulated in step S205 to perform a process of updating the existing dimensional compression model included in the analysis information acquired in step S203 (step S209), and the process proceeds to step S210. For example, the processor 11 can generate a dimensional compression model by using the existing monitoring data related to the analyzed chamber 3 included in the analysis information and new monitoring data related to the added chamber 3, thereby updating the dimensional compression model.

The processor 11 generates analysis information that includes information such as monitoring data, a dimensional compression model, label information, a covariance matrix, and statistics, based on the results of the analysis process in step S202 or the results of the analysis process in steps S203 to S209 (step S210). The processor 11 stores the analysis information generated in step S210 in the storage 12 (step S211), and completes the process.

Further, the information processing apparatus 1 according to the second embodiment performs a temporal change monitoring process of the plurality of chambers 3 based on various statistics stored as the analysis information. The information processing apparatus 1 calculates the above-described statistics (statistics of the Mahalanobis distance of the monitoring data in a fleet unit, statistics of the monitoring data for each sensor in a fleet unit, statistics of the Mahalanobis distance of the monitoring data in a chamber unit, and statistics of the monitoring data for each sensor in a chamber unit) at a predetermined cycle, such as once a day or once every 10 hours of operation, based on the monitoring data acquired from the plurality of chambers 3. The information processing apparatus 1 stores the statistics that have been repeatedly calculated as the analysis information, and compares the statistics with previous statistics each time the latest statistics are calculated to determine the presence or absence of an abnormality related to a temporal change of the chamber 3. The information processing apparatus 1 can determine the presence or absence of an abnormality based on, for example, whether the latest statistics are within a predetermined range (for example, 30 or less) for variations in previous statistics, or based on, for example, whether a difference between the latest statistics and immediately preceding statistics exceeds a threshold value.

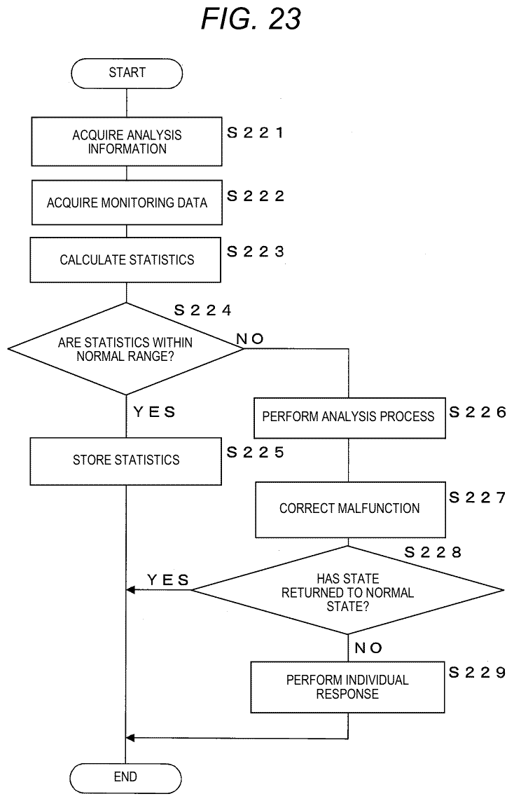

FIG. 23 is a flowchart illustrating a procedure of a temporal change monitoring process performed by the information processing apparatus 1 according to the second embodiment. The processor 11 of the information processing apparatus 1 according to the second embodiment acquires the analysis information stored in the storage 12 by reading the analysis information (step S221). The processor 11 acquires the monitoring data stored in the monitoring data storage 12c (step S222). The processor 11 calculates at least one of the statistics of the Mahalanobis distance of the monitoring data in a fleet unit, the statistics of the monitoring data for each sensor in a fleet unit, statistics of the Mahalanobis distance of the monitoring data in a chamber unit, or statistics of the monitoring data for each sensor in a chamber unit, based on the monitoring data read in step S222 (step S223).

The processor 11 compares the past statistics included in the analysis information acquired in step S221 with the latest statistics calculated in step S223 to determine whether the latest statistics are within the normal range for variations in past statistics (step S224). When the latest statistics are within the normal range (S224: YES), the processor 11 stores the statistics calculated in step S223 in the analysis information (step S225), and completes the process.

When the latest statistics are not within the normal range for the variations of the past statistics (S224: NO), the processor 11 performs, for example, the analysis process illustrated in FIG. 22 (step S226).

Based on the analysis process, the processor 11 performs various processes for correcting malfunctions or the like that have occurred in the chamber 3 (step S227). The process for correcting malfunctions or the like may include, for example, a process of confirming details of input/output data of the sensor, which are specified as factors of the malfunctions through the analysis process, a calibration process of the sensor, a replacement process of the sensor, or an operation confirmation process of the replaced sensor. The processor 11 determines whether a state of the chamber 3 has returned to a normal state through the process in step S227 (step S228). In order to perform the determination in step S228, the information processing apparatus 1 may perform a process such as a process of a wafer by the chamber 3 to collect the monitoring data, for example.

When the state of the chamber 3 does not return to the normal state (S228: NO), the processor 11 performs an appropriate individual response such as stopping the operation of the abnormal chamber 3 or requesting maintenance of the abnormal chamber 3 (step S229), and completes the process. Each process illustrated in steps S227 to S229 described above does not necessarily have to be performed by the information processing apparatus 1 alone, and may be performed through cooperation with a user such as an administrator of the information processing system according to the present embodiment, for example. In this case, the processor 11 receives an operation of the user, and performs the process for correcting malfunctions or the like, the process of determining whether the chamber 3 has returned to the normal state, or the process of an individual response to the abnormal chamber 3, as appropriate.

When the state of the chamber 3 has returned to the normal state (S228: YES), the processor 11 completes the process.

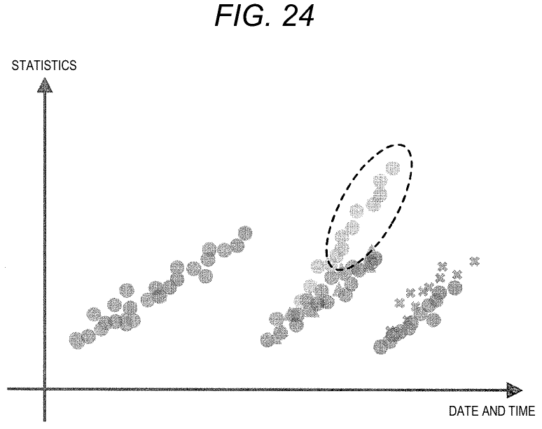

FIG. 24 is a schematic diagram for explaining the temporal change monitoring process. FIG. 24 is a graph in which a horizontal axis represents a date and time, and a vertical axis represents statistics, which represents a temporal change in statistics related to certain sensors in the chamber 3. The information processing apparatus 1 may calculate statistical values of the monitoring data acquired from the chamber 3 at predetermined cycles such as once a day or once every 10 hours of operation, may store the calculated statistical values as analysis information, and may display a graph as illustrated in FIG. 24 on the display 14. Each dot illustrated in the graph of the present example represents statistical values obtained from the sensor as the results of performing the process on one wafer.

In the sensor of the present example, output values tend to increase as the process in the chamber 3 is performed. However, the sensor returns to an initial state after the maintenance is performed. In the graph illustrated in FIG. 24, the chamber 3 having a large increase in the output values of the sensor according to the time elapse exists in an area surrounded by a broken line. The statistics of the monitoring data are periodically calculated and stored as analysis information, and changes, variations, or the like in the statistics are periodically confirmed, so that an abnormality or the like in the chamber 3 may be detected. In addition, in the present example, measures such as repair and maintenance are performed in response to the detection of an abnormality or the like. FIG. 24 illustrates that the output values of the sensor return to the initial state by the measures, and no abnormality has occurred thereafter.

In the information processing system according to the second embodiment configured as described above, the information processing apparatus 1 acquires monitoring data which includes a plurality of items related to a state of each process performed by the chamber (target apparatus) 3. The information processing apparatus 1 acquires monitoring data related to the analyzed chamber 3 or analysis information including the dimensional compression model generated based on the monitoring data. The information processing apparatus 1 inputs the monitoring data of the target chamber 3 into the dimensional compression model generated based on the monitoring data related to the analyzed apparatus to convert the monitoring data into a low-dimensional representation. The information processing apparatus 1 displays (outputs) the monitoring data converted into the low-dimensional representation on the display 14. Thus, the information processing system according to the present embodiment can use the dimensional compression model generated based on the monitoring data of the analyzed chamber 3 to convert the monitoring data of the target chamber 3 that is newly added into the low-dimensional representation and present to the user. The information processing system can support the analysis of the monitoring data obtained from the chamber 3.

In addition, in the information processing system according to the second embodiment, the information processing apparatus 1 determines the presence or absence of the analysis information, and uses the analysis information to perform dimensional compression of the monitoring data when the analysis information exists. When the analysis information does not exist, the information processing apparatus 1 generates a dimensional compression model based on the acquired monitoring data of the target chamber 3, and performs dimensional compression of the monitoring data. Thus, the information processing system according to the present embodiment can support analysis of the monitoring data obtained from the target chamber 3 regardless of the presence or absence of the analysis information related to the analyzed chamber 3.

In addition, in the information processing system according to the second embodiment, the information processing apparatus 1 stores the monitoring data related to the analyzed chamber 3 and the dimensional compression model generated based on the monitoring data as analysis information. Thus, the information processing apparatus 1 can perform dimensional compression of the monitoring data of the target chamber 3 by using the stored dimensional compression model without newly generating the dimensional compression model. In addition, the information processing apparatus 1 can generate a new dimensional compression model by using the stored monitoring data related to the analyzed chamber 3 and the newly acquired monitoring data of the target chamber 3.

In addition, in the information processing system according to the second embodiment, the monitoring data includes a plurality of items classified into a plurality of categories such as a pressure category and a temperature category, for example. The information processing apparatus 1 stores the dimensional compression model for each category as the analysis information, and converts the monitoring data into a low-dimensional representation for each category and displays for each category by using the stored dimensional compression model. Thus, the information processing system according to the second embodiment can visualize the monitoring data for each category and present the monitoring data to the user. The information processing system can support, for example, verification of which category the factors or causes of malfunctions or individual differences in the chamber 3 is based on.

FIG. 3 illustrates “pressure category” and “temperature category” as categories. However, these are examples, and the classification of the categories may be performed in any manner. For example, a plurality of category types such as pressure, temperature, and the like may be combined to form one category, such as “pressure and temperature category”. Further, for example, the same type of category may be further divided into a plurality of categories, such as “pressure category 1” and “pressure category 2”. This applies to both the information processing systems of the first embodiment and the second embodiment.

Further, in the information processing system according to the second embodiment, various statistics of the monitoring data related to the analyzed chamber 3 are included in the analysis information. The information processing apparatus 1 calculates statistics of the monitoring data related to the chamber 3 that is an analysis target. The information processing apparatus 1 determines the presence or absence of an abnormality or a temporal change state of the chamber 3 that is the analysis target, based on a comparison between the statistics of the monitoring data related to the analyzed chamber 3 and the statistics of the monitoring data related to the chamber 3 that is the analysis target. Thus, the information processing system according to the second embodiment can support analysis such as the presence or absence of an abnormality or temporal change of the chamber 3 that is the analysis target, based on the statistics related to the analyzed chamber 3.

Since the other configurations of the information processing system according to the second embodiment are the same as those of the information processing system according to the first embodiment, the same reference numerals are given to the same locations, and a detailed description thereof will be omitted.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

According to the present disclosure, it can be expected to support the analysis of monitoring data obtained from a target apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. An information processing method comprising, by an information processing apparatus:
acquiring monitoring data which includes a plurality of items related to a state of each process performed by a target apparatus;
generating a dimensional compression model for compressing the number of dimensions of the monitoring data;
inputting the monitoring data into the dimensional compression model to convert the monitoring data into a low-dimensional representation; and
outputting the monitoring data converted into the low-dimensional representation.

2. The information processing method according to claim 1,
wherein the monitoring data includes a plurality of items classified into a plurality of categories, and
the information processing apparatus
generates the dimensional compression model for each category, and
inputs the monitoring data into a dimensional compression model corresponding to each category to convert the monitoring data into a low-dimensional representation for each category.

3. The information processing method according to claim 1,
wherein the information processing apparatus
acquires the monitoring data about a plurality of the target apparatuses,
calculates a first distance of each monitoring data with respect to a monitoring data group of the plurality of target apparatuses,
calculates a second distance of each monitoring data with respect to a monitoring data group for each target apparatus, and
converts the monitoring data into a low-dimensional representation in which the first distance and the second distance are represented as dimensions.

4. The information processing method according to claim 3,
wherein the information processing apparatus
calculates a first covariance matrix for the monitoring data group of the plurality of target apparatuses,
calculates a Mahalanobis distance of each monitoring data based on the first covariance matrix as the first distance,
calculates a second covariance matrix for the monitoring data group of each target apparatus, and
calculates a Mahalanobis distance of each monitoring data based on the second covariance matrix as the second distance.

5. The information processing method according to claim 3,
wherein one or more monitoring data groups are selected based on the monitoring data converted into the low-dimensional representation,
a dimensional compression model for compressing the number of dimensions of the monitoring data included in the monitoring data group is generated for each selected monitoring data group,
the monitoring data is input into the dimensional compression model to convert the monitoring data into a low-dimensional representation, and
the monitoring data converted into the low-dimensional representation is output for each monitoring data group.

6. The information processing method according to claim 1,
wherein the information processing apparatus
acquires monitoring data about a plurality of the target apparatuses,
converts the monitoring data about the plurality of target apparatuses into a low-dimensional representation,
selects one or more monitoring data groups based on the monitoring data converted into the low-dimensional representation,
converts the monitoring data into a low-dimensional representation for each selected monitoring data group, and
outputs the monitoring data for each monitoring data group converted into the low-dimensional representation.

7. The information processing method according to claim 1,
wherein the information processing apparatus
acquires first label information related to a class classification assigned to the monitoring data,
selects a predetermined number of dimensions based on the first label information about the monitoring data converted into the low-dimensional representation by the dimensional compression model, and
outputs the monitoring data in the selected dimensions.

8. The information processing method according to claim 1,
wherein the information processing apparatus
acquires first label information related to a class classification assigned to the monitoring data,
determines a reference for scale conversion based on the monitoring data classified into a predetermined class in the first label information,
performs scale conversion of the monitoring data of the predetermined class and a class other than the predetermined class based on the determined reference, and
generates the dimensional compression model based on the scale-converted monitoring data.

9. The information processing method according to claim 1,
wherein the information processing apparatus
acquires first label information related to a class classification assigned to the monitoring data,
generates a self-encoder based on the monitoring data classified into a predetermined class in the first label information,
calculates a difference between an input and an output of the self-encoder when monitoring data of the predetermined class and a class other than the predetermined class is input into the self-encoder, and
generates the dimensional compression model for compressing the number of dimensions of the calculated difference.

10. The information processing method according to claim 1,
wherein the information processing apparatus
assigns second label information to the monitoring data of the low-dimensional representation that has been output as data, and
generates a prediction model for predicting the second label information about an input of the monitoring data, based on the monitoring data to which the second label information is assigned.

11. The information processing method according to claim 10,
wherein the information processing apparatus
calculates a degree of importance of a plurality of items included in the monitoring data based on the generated prediction model,
selects a predetermined number of items for the monitoring data based on the degree of importance, and
outputs the monitoring data for the selected item.

12. The information processing method according to claim 1,
wherein the information processing apparatus
acquires time series data from the target apparatus,
divides the process performed by the target apparatus into a plurality of periods, and calculates statistical values in each period of the acquired time series data,
receives a selection of the period based on the calculated statistical values, and
stores the statistical values of the periods during which the selection is received, as the monitoring data.

13. The information processing method according to claim 10,
wherein the process performed by the target apparatus includes any one of a substrate processing process, a substrate transfer process, a wafer-less dry cleaning process, a seasoning process, a plasma health check process, or a sensor automatic check process.

14. The information processing method according to claim 1,
wherein the information processing apparatus outputs the monitoring data converted into the low-dimensional representation using a histogram, a box and whisker plot, a violin chart, a scattering diagram, a density contour diagram, or a heat map.

15. An information processing method comprising, by an information processing apparatus:
acquiring monitoring data which includes a plurality of items related to a state of each process performed by an analysis target apparatus;
acquiring analysis information which includes monitoring data related to an analyzed apparatus or a dimensional compression model generated based on the monitoring data;
inputting the monitoring data of the acquired analysis target apparatus into the dimensional compression model generated based on the acquired monitoring data included in the analysis information or a dimensional compression model included in the analysis information, to convert the monitoring data into a low-dimensional representation; and
outputting the monitoring data converted into the low-dimensional representation.

16. The information processing method according to claim 15,
wherein a presence or absence of the analysis information is determined,
a dimensional compression model for compressing the number of dimensions of the monitoring data is generated when it is determined that there is no analysis information,
the monitoring data is input into the dimensional compression model to convert the monitoring data into a low-dimensional representation; and
the monitoring data converted into the low-dimensional representation is output.

17. The information processing method according to claim 16,
wherein the monitoring data and the dimensional compression model generated based on the monitoring data are stored as the analysis information.

18. The information processing method according to claim 17,
wherein the monitoring data includes a plurality of items classified into a plurality of categories,
the dimensional compression model is generated for each category, and
the monitoring data is input into a dimensional compression model corresponding to each category to convert the monitoring data into a low-dimensional representation for each category.

19. The information processing method according to claim 15,
wherein the analysis information includes statistics of the monitoring data related to the analyzed apparatus,
the statistics of the monitoring data of the analysis target apparatus are calculated, and
a state of the analysis target apparatus is determined based on a comparison between the statistics of the analyzed apparatus and the statistics of the analysis target apparatus.

20. The information processing method according to claim 19,
wherein statistics related to a plurality of the apparatuses are calculated based on the monitoring data of the plurality of apparatuses, and
statistics related to each apparatus are calculated based on the monitoring data of each apparatus.

21. The information processing method according to claim 19,
wherein the apparatus includes a plurality of sensors for acquiring the monitoring data,
statistics related to the plurality of sensors are calculated based on the monitoring data of the plurality of sensors, and
statistics related to each sensor are calculated based on the monitoring data of each sensor.

22. The information processing method according to claim 21,
wherein a distance of each monitoring data with respect to a monitoring data group of the plurality of sensors is calculated, and
statistics related to the calculated distance are calculated.

23. The information processing method according to claim 15,
wherein the monitoring data of the analysis target apparatus converted into the low-dimensional representation and the monitoring data of the analyzed apparatus converted into the low-dimensional representation are output together.

24. A non-transitory recording medium in which a computer program is recorded, the computer program for causing a computer to perform a process comprising:
acquiring monitoring data which includes a plurality of items related to a state of each process performed by a target apparatus;
generating a dimensional compression model for compressing the number of dimensions of the monitoring data;
inputting the monitoring data into the dimensional compression model to convert the monitoring data into a low-dimensional representation; and
outputting the monitoring data converted into the low-dimensional representation.

25. A non-transitory recording medium in which a computer program is recorded, the computer program for causing a computer to perform a process comprising:
acquiring monitoring data which includes a plurality of items related to a state of each process performed by an analysis target apparatus;
acquiring analysis information which includes monitoring data related to an analyzed apparatus or a dimensional compression model generated based on the monitoring data;
inputting the monitoring data of the acquired analysis target apparatus into the dimensional compression model generated based on the acquired monitoring data included in the analysis information or a dimensional compression model included in the analysis information, to convert the monitoring data into a low-dimensional representation; and
outputting the monitoring data converted into the low-dimensional representation.

26. An information processing apparatus comprising:
an acquirer configured to acquire monitoring data which includes a plurality of items related to a state of each process performed by a target apparatus;
a generator configured to generate a dimensional compression model for compressing the number of dimensions of the monitoring data;
a converter configured to input the monitoring data into the dimensional compression model to convert the monitoring data into a low-dimensional representation; and
an outputter configured to output the monitoring data converted into the low-dimensional representation.

27. An information processing apparatus comprising:
a monitoring data acquirer configured to acquire monitoring data which includes a plurality of items related to a state of each process performed by an analysis target apparatus;
an analysis information acquirer configured to acquire analysis information which includes monitoring data related to an analyzed apparatus or a dimensional compression model generated based on the monitoring data;
a converter configured to input the monitoring data of the acquired analysis target apparatus into the dimensional compression model generated based on the acquired monitoring data included in the analysis information or a dimensional compression model included in the analysis information, to convert the monitoring data into a low-dimensional representation; and
an outputter configured to output the monitoring data converted into the low-dimensional representation.
